(19) United States
(12) Patent Application Publication
(10) Pub. No.: US 2026/0334064 A1
(43) Pub. Date: Oct. 22, 2026

(54) WINDOW MODULE, DISPLAY DEVICE INCLUDING THE SAME AND ELECTRONIC DEVICE INCLUDING THE SAME

(71) Applicant: Samsung Display Co., Ltd., Yongin-Si (KR)

(72) Inventors: HYEONMI LEE, Yongin-si (KR); JUYOUNG YOON, Yongin-si (KR); DAHYE KIM, Yongin-si (KR); MANSOO KIM, Yongin-si (KR); HYUN-HYANG KIM, Yongin-si (KR)

(21) Appl. No.: 19/466,657

(22) Filed: Feb. 2, 2026

(30) Foreign Application Priority Data
Mar. 28, 2025 (KR) 10-2025-0040146

(51) Int. Cl. H10K 59/80

(52) U.S. Cl. CPC H10K 59/8791

(57) ABSTRACT

The present disclosure relates to a window module capable of implementing low reflectivity and improving durability, and includes a base substrate, an anti-fingerprint layer arranged on the base substrate, and an anti-reflective layer between the base substrate and the anti-fingerprint layer. The anti-reflective layer includes a first refractive layer under the anti-fingerprint layer, a second refractive layer under the first refractive layer and having a second thickness equal to or greater than 0.4 times a first thickness of the first refractive layer and equal to or less than 1.5 times the first thickness, and a third refractive layer between the second refractive layer and the base substrate, having a refractive index greater than the first refractive layer and a thickness of 100 nm or more.

### CROSS-REFERENCE TO RELATED APPLICATION(S)

This application claims priority under 35 U.S.C. § 119 to Korean Patent Application No. 10-2025-0040146, filed on Mar. 28, 2025, which is hereby incorporated by reference for all purposes as if fully set forth herein.

### BACKGROUND

### 1. Field

Embodiments relate to a window module, a display device including the same, and an electronic device including the same. More particularly, the embodiments relate to the window module controlling a light reflectivity, the display device including the same, and the electronic device including the same.

### 2. Description of the Related Art

A display device may be a device that displays images to provide visual information to the user. The display device may include a display panel containing pixels that emit light and a window module to protect the display panel.

Recently, according to a usage of display devices in various forms, research may be conducted on the window module with diverse shapes and functions. Specifically, structures of the window module may be developed to enhance a durability of the display device and reduce reflectivity, thereby improving display quality of the display device by controlling light emitted from the display panel or external light.

### SUMMARY

Embodiments provide a window module with reduced light reflectivity and improved durability.

Embodiments provide a display device including the window module.

Embodiments provide an electronic device including the window module.

A window module according to an embodiment includes a base substrate, an anti-fingerprint layer on the base substrate, and an anti-reflective layer on the base substrate and the anti-fingerprint layer. The anti-reflective layer includes a first refractive layer under the anti-fingerprint layer, a second refractive layer under the first refractive layer, and having a second thickness equal to or greater than about 0.4 times a first thickness of the first refractive layer and equal to or less than about 1.5 times the first thickness, and a third refractive layer between the second refractive layer and the base substrate in a cross-sectional view, having a refractive index greater than a refractive index of the first refractive layer, and a thickness of about 100 nm or more.

In an embodiment, the window module may further include a fourth refractive layer between the second refractive layer and the third refractive layer in the cross-sectional view, and having a thickness of about 50 nm or more and a fifth refractive layer between the third refractive layer and the base substrate in the cross-sectional view, and having a refractive index less than the refractive index of the third refractive layer.

In an embodiment, the fifth refractive layer may have a multi-layered structure including a plurality of sub-refractive layers

In an embodiment, the sub-refractive layers may include at least one first sub-refractive layer having a refractive index equal to or less than about 1.8 and at least one second sub-refractive layer having a refractive index different from the refractive index of the first sub-refractive layer. The first sub-refractive layer and the second sub-refractive layer define the fifth refractive layer by being stacked with each other

In an embodiment, the window module may further include a first dummy structure between the fifth refractive layer and the base substrate in the cross-sectional view. The first dummy structure may include a first dummy layer under the fifth refractive layer and a second dummy layer under the first dummy layer, and having a refractive index less than a refractive index of the first dummy layer.

In an embodiment, the window module may further include a second dummy structure between the first dummy structure and the base substrate in the cross-sectional view. The second dummy structure may include a third dummy layer under the second dummy layer, and having a refractive index greater than the refractive index of the second dummy layer and a fourth dummy layer under the third dummy layer, and having a refractive index less than the refractive index of the third dummy layer.

In an embodiment, the second dummy layer may have a multi-layered structure including at least three sub-refractive layers

In an embodiment, the window module may further include a first dummy structure between the third refractive layer and the fifth refractive layer in the cross-sectional view. The first dummy structure may include a first dummy layer under the fifth refractive layer and a second dummy layer under the first dummy layer, and having a refractive index greater than a refractive index of the first dummy layer.

In an embodiment, the window module may further include a second dummy structure between the first dummy structure and the fifth refractive layer in the cross-sectional view. The second dummy structure may include a third dummy layer under the second dummy layer, and having a refractive index less than the refractive index of the second dummy layer and a fourth dummy layer under the third dummy layer, and having a refractive index greater than the refractive index of the third dummy layer.

In an embodiment, the refractive index of the first refractive layer, a refractive index of the fourth refractive layer, and the refractive index of the fifth refractive layer may be equal to or less than about 1.8, and a refractive index of the second refractive layer and the refractive index of the third refractive layer may be equal to or greater than about 1.9.

In an embodiment, the first refractive layer, the fourth refractive layer, and the fifth refractive layer may include at least one selected from a group consisting silicon oxide (SiOₓ) and silicon oxynitride (SiON), and the second refractive layer, and the third refractive layer may include silicon nitride (SiNₓ).

In an embodiment, the first thickness of the first refractive layer may be about 70 nm to about 120 nm.

A display device according to an embodiment includes a display panel including a planar area and a curved area adjacent to the planar area, and including a plurality of pixels and a window module in the planar area and the curved area on the display panel. The window module includes a base substrate, an anti-fingerprint layer on the base substrate, and an anti-reflective layer on the base substrate and the anti-fingerprint layer. The anti-reflective layer may include a first refractive layer under the anti-fingerprint layer, a second refractive layer under the first refractive layer, and having a second thickness equal to or greater than about 0.4 times a first thickness of the first refractive layer and equal to or less than about 1.5 times the first thickness, and a third refractive layer between the second refractive layer and the base substrate in a cross-sectional view, having a refractive index greater than a refractive index of the first refractive layer, and a thickness of about 100 nm or more.

In an embodiment, the window module may include a fourth refractive layer between the second refractive layer and the third refractive layer in the cross-sectional view, and having a thickness of about 50 nm or more and a fifth refractive layer between the third refractive layer and the base substrate in the cross-sectional view, and having a refractive index less than the refractive index of the third refractive layer.

In an embodiment, the fifth refractive layer may have a multi-layered structure including a plurality of sub-refractive layers.

In an embodiment, the window module may include at least one dummy structure between the fifth refractive layer and the base substrate, and in which two dummy layers having different refractive indexes are stacked.

In an embodiment, the refractive index of the first refractive layer, a refractive index of the fourth refractive layer, and the refractive index of the fifth refractive layer may be equal to or less than about 1.8, and a refractive index of the second refractive layer and the refractive index of the third refractive layer may be equal to or greater than about 1.9.

In an embodiment, the first thickness of the first refractive layer may be about 70 nm to about 120 nm.

An electronic device according to an embodiment includes a power module and a display device to which power from the power module is configured to be supplied, and including a display panel and a window module on the display panel. The window module includes a base substrate, an anti-fingerprint layer on the base substrate, and an anti-reflective layer on the base substrate and the anti-fingerprint layer. The anti-reflective layer includes a first refractive layer under the anti-fingerprint layer, a second refractive layer under the first refractive layer, and having a second thickness equal to or greater than about 0.4 times a first thickness of the first refractive layer and equal to or less than about 1.5 times the first thickness, and a third refractive layer between the second refractive layer and the base substrate in the cross-sectional view, having a refractive index greater than a refractive index of the first refractive layer, and a thickness of about 100 nm or more.

In an embodiment, the window module may include a fourth refractive layer between the second refractive layer and the third refractive layer in the cross-sectional view, and having a thickness of about 50 nm or more and a fifth refractive layer between the third refractive layer and the base substrate in the cross-sectional view, and having a refractive index less than the refractive index of the third refractive layer.

In a window module according to embodiments of the present disclosure, an anti-reflective layer may have a structure in which low-refractive-index layers and high-refractive-index layers are alternately stacked. In addition, a first thickness of a first refractive layer, which is a low-refractive-index layer located at the uppermost layer of the anti-reflective layer, may be about 70 nm to about 120 nm. In addition, a second thickness of a second refractive layer, which is a high-refractive-index layer located under the first refractive layer, may be equal to or greater than a value obtained by multiplying the first thickness of the first refractive layer by about 0.4 and may be equal to or less than the value obtained by multiplying the first thickness by about 1.5. In addition, a third thickness of a fifth refractive layer, which is a low-refractive-index layer located third from the uppermost layer of the anti-reflective layer among the low-refractive-index layers included in the anti-reflective layer, may be about 50 nm or more. In addition, a fourth thickness of an eighth refractive layer included in the anti-reflective layer may be the largest among the high-refractive-index layers. In addition, a fifth thickness of a ninth refractive layer included in the anti-reflective layer may be about 20 nm or more. Accordingly, color difference generated between light viewed in the flat area of the window module and light viewed in the curved area of the window module may be reduced. Furthermore, reflectivity of light reflected from a surface of the window module may be reduced.

In the display device according to embodiments of the present disclosure, since the display device includes the window module, surface reflectivity may be reduced, thereby providing users with images with improved display quality.

In an electronic device according to embodiments of the present disclosure, since the electronic device includes the display device, surface reflectivity may be reduced, thereby improving quality of images provided to users and providing images with stable operation.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating a display device according to an embodiment of the present disclosure.

FIG. 2 is an exploded perspective view illustrating the display device of FIG. 1

FIG. 3 is a cross-sectional view illustrating a portion of the display device in a plan view of FIG. 1.

FIG. 4 is a cross-sectional view illustrating a window module taken along the line I-I′ of FIG. 2.

FIG. 5 is a cross-sectional view illustrating an anti-reflective layer taken along the line I-I′ of FIG. 2

FIG. 6 is a cross-sectional view illustrating an example of a portion of the window module of FIG. 2.

FIG. 7 is a cross-sectional view illustrating a portion of a display panel of FIG. 2.

FIG. 8 is a cross-sectional view illustrating an example of a portion of the window module of FIG. 2.

FIG. 9 is a cross-sectional view illustrating an example of a portion of the window module of FIG. 2.

FIG. 10 is a cross-sectional view illustrating an example of a portion of the window module of FIG. 2.

FIG. 11 is a cross-sectional view illustrating an example of a portion of the window module of FIG. 2.

FIG. 12 is a cross-sectional view illustrating an example of a portion of the window module of FIG. 2.

FIG. 13 is a cross-sectional view illustrating an example of a portion of the window module of FIG. 2.

FIG. 14 is a cross-sectional view illustrating an example of a portion of the window module of FIG. 2.

FIG. 15 is a cross-sectional view illustrating an example of a portion of the window module of FIG. 2.

FIG. 16 is a cross-sectional view illustrating an example of a portion of the window module of FIG. 2.

FIG. 17 is a cross-sectional view illustrating an example of a portion of the window module of FIG. 2.

FIGS. 18, 19, 20, and 21 are views for explaining effects of the window module according to embodiments of the present disclosure.

FIG. 22 is a block diagram of an electronic device according to an embodiment of the present disclosure.

FIG. 23 is a schematic view of electronic devices according to various embodiments.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +10% or +5% of the stated value.

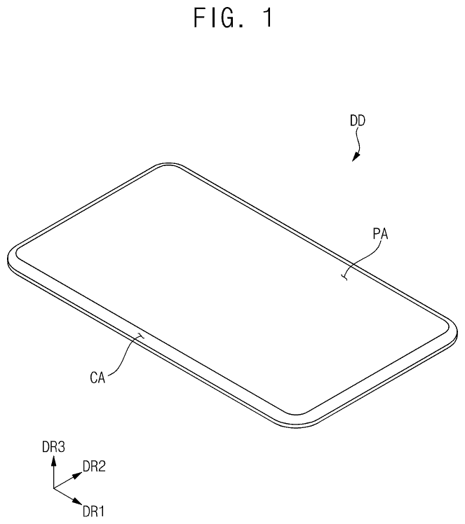

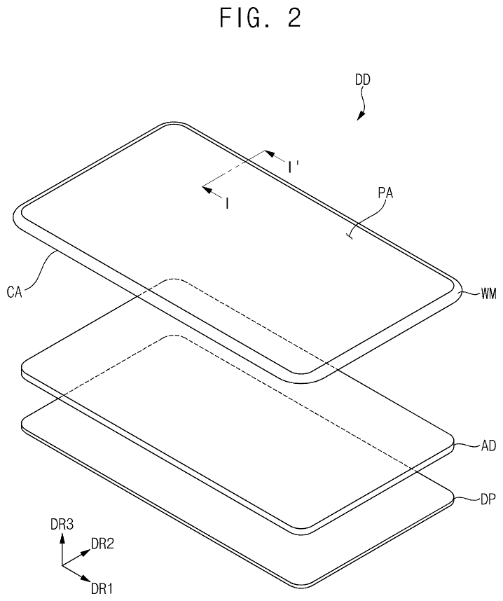

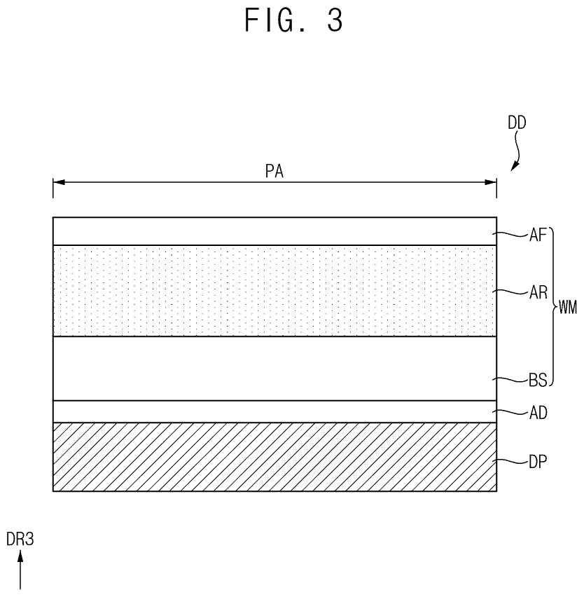

FIG. 1 is a perspective view illustrating a display device DD according to an embodiment of the present disclosure. FIG. 2 is an exploded perspective view illustrating the display device DD of FIG. 1 FIG. 3 is a cross-sectional view illustrating a portion of the display device DD in a plan view of FIG. 1.

In the present disclosure, a plane may be defined by a first direction DR1 and a second direction DR2 intersecting the first direction DR1. For example, the second direction DR2 may be perpendicular to the first direction DR1. In addition, a third direction DR3 may be a normal direction of the plane. That is, the third direction DR3 may be perpendicular to the plane defined by the first direction DR1 and the second direction DR2.

Referring to FIGS. 1, 2, and 3, the display device DD according to an embodiment of the present disclosure may include a planar area PA and a curved area CA. The curved area CA may be bent with a predetermined curvature from one side of the planar area PA. For example, the curved area CA may be bent from one side of the planar area PA toward a direction opposite to the third direction DR3. In an embodiment, a portion of the display device DD that is adjacent to an edge of the planar area PA and faces outward may be defined as the curved area CA. However, a bending direction of the curved area CA according to embodiments of the present disclosure may not be limited thereto.

The display device DD may include a display panel DP, an adhesive layer AD, and a window module WM. The window module WM may include a base substrate BS, an anti-reflective layer AR, and an anti-fingerprint layer AF. Since the display device DD includes the planar area PA and the curved area CA, the display panel DP and the window module WM may also include the planar area PA and the curved area CA.

The display panel DP may emit light to display an image. For example, the display panel DP may include a plurality of light-emitting pixels. The pixels may be located in the planar area PA of the display device DD. For example, the pixels may be arranged in a matrix form along the first direction DR1 and the second direction DR2 in the planar area PA. However, the arrangement of the pixels according to the embodiments of the present disclosure may not be limited thereto, and the pixels may also be arranged in the curved area CA.

The window module WM may be arranged on the display panel DP. For example, the window module WM may be arranged in the planar area PA and the curved area CA.

The base substrate BS may be arranged on the display panel DP. In an embodiment, the base substrate BS may include glass, quartz, plastic, and the like. For example, the plastic included in the base substrate BS may include polyimide (PI), polyethylene terephthalate (PET), polyethylene naphthalene (PEN), polypropylene (PP), polycarbonate (PC), polystyrene (PS), polysulfone (PSul), polyethylene (PE), polyphthalamide (PPA), polyethersulfone (PES), polyarylate (PAR), polycarbonate oxide (PCO), modified polyphenylene oxide (MPPO), and the like. These materials may be used alone or in combination. However, the materials included in the base substrate BS according to the embodiments of the present disclosure may not be limited thereto, and the base substrate BS may include various types of optically transparent materials capable of providing images provided from the display panel DP of the display device DD to a user.

The adhesive layer AD may be arranged between the display panel DP and the base substrate BS. In an embodiment, the adhesive layer AD may include an adhesive material. For example, the adhesive layer AD may bond the display panel DP and the window module WM to each other. In an embodiment, the adhesive layer AD may include a pressure sensitive adhesive (PSA), an optically clear adhesive (OCA), an optically clear resin (OCR), and the like. These may be used alone or in combination.

The anti-reflective layer AR may be arranged on the base substrate BS. The anti-reflective layer AR may reduce the reflectivity of light reflected from the surface of the display device DD. For example, the anti-reflective layer AR may guide incident light and reflected light to interfere with each other destructively by alternately stacking refractive layers having different refractive indices. Accordingly, the anti-reflective layer AR may reduce external light reflection and prevent glare from occurring to a user of the display device DD.

The anti-fingerprint layer AF may be arranged under the anti-reflective layer AR. In an embodiment, the anti-fingerprint layer AF may include a fingerprint-resistant material. For example, the fingerprint-resistant material may include a metal oxide such as titanium oxide (TiOx), a silicon-based compound, a fluorine-based compound, and the like. These may be used alone or in combination. However, the fingerprint-resistant materials included in the anti-fingerprint layer AF according to the embodiments of the present disclosure may not be limited thereto.

In an embodiment, the anti-fingerprint layer AF may be formed by coating the fingerprint-resistant material on the anti-reflective layer AR. For example, the coating method of the anti-fingerprint layer AF may include a wet coating method or a dry coating method. However, the method of manufacturing the anti-fingerprint layer AF according to the embodiments of the present disclosure may not be limited thereto.

In addition, a structure of the window module WM according to the embodiments of the present disclosure may not be limited thereto, and the window module WM may further include a hard coating layer arranged between the base substrate BS and the anti-reflective layer AR. For example, the hard coating layer may include a photo-curable resin and fine particles dispersed in the photo-curable resin.

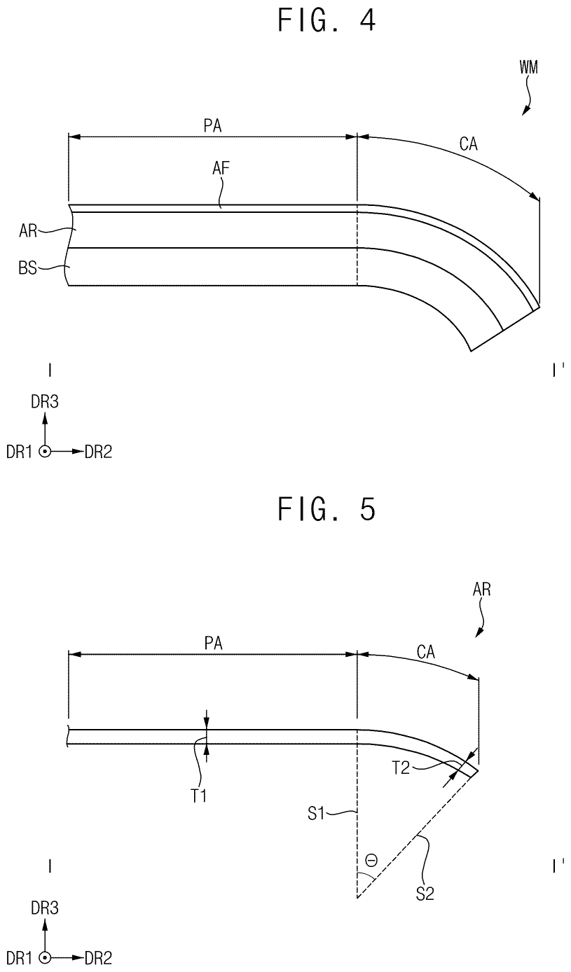

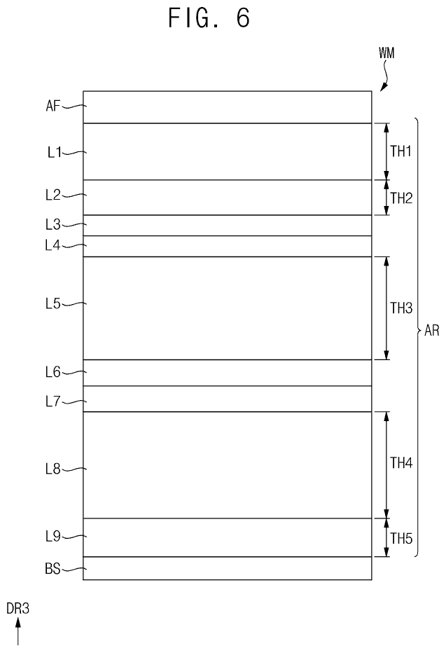

FIG. 4 is a cross-sectional view illustrating the window module WM taken along the line I-I′ of FIG. 2. FIG. 5 is a cross-sectional view illustrating the anti-reflective layer AR taken along the line I-I′ of FIG. 2

Referring to FIGS. 4 and 5, a portion of the window module WM located in the planar area PA may be substantially flat. In addition, a portion of the window module WM located in the curved area CA may extend from the portion of the window module WM located in the planar area PA and be bent toward a direction opposite to the third direction DR3. Since the window module WM includes the anti-reflective layer AR, the anti-reflective layer AR may have substantially the same cross-sectional structure as the window module WM. For example, a portion of the anti-reflective layer AR located in the planar area PA may be substantially flat. In addition, a portion of the anti-reflective layer AR located in the curved area CA may extend from the portion of the anti-reflective layer AR located in the planar area PA and be bent toward a direction opposite to the third direction DR3.

In an embodiment, a first thickness T1, which is the thickness of the anti-reflective layer AR located in the planar area PA, may be substantially uniform across the planar area PA. For example, the anti-reflective layer AR in the planar area PA may be formed to have a substantially uniform thickness. A thickness of the anti-reflective layer AR located in the curved area CA may vary. For example, the second thickness T2, which is the thickness of the anti-reflective layer AR, may decrease as the anti-reflective layer AR approaches the curved area CA from the boundary between the planar area PA and the curved area CA. Specifically, as the base substrate BS is bent in the curved area CA, the second thickness T2 of the anti-reflective layer AR formed on the curved area CA of the base substrate BS may be less than the first thickness T1 of the anti-reflective layer AR formed on the planar area PA of the base substrate BS. In an embodiment, the first thickness T1 may be greater than the second thickness T2. However, the relationship between the first thickness T1 and the second thickness T2 according to the embodiments of the present disclosure may not be limited thereto, and the relationship between the first thickness T1 and the second thickness T2 may vary depending on the curvature and the bending direction of the curved area CA.

In an embodiment, the second thickness T2 may be defined according to an [Equation 1] below.

T2=T1×cos θ [Equation 1]

Here, θ is an angle between a first extending plane S1 and a second extending plane S2.

Specifically, the first extending plane S1 may be a plane parallel to the normal direction of a surface of the anti-reflective layer AR located in the planar area PA. In addition, the second extending plane S2 may be a plane parallel to the normal direction of a surface of the anti-reflective layer AR located in the curved area CA.

As a portion of the anti-reflective layer AR is bent in the curved area CA, when the anti-reflective layer AR is formed on the base substrate BS, the second thickness T2 of the anti-reflective layer AR in the curved area CA may be reduced compared to the first thickness T1 of the anti-reflective layer AR in the planar area PA, which may cause a path difference between light observed from the curved area CA and light observed from the planar area PA. Accordingly, a color difference may be generated between the light observed from the planar area PA and the light observed from the curved area CA.

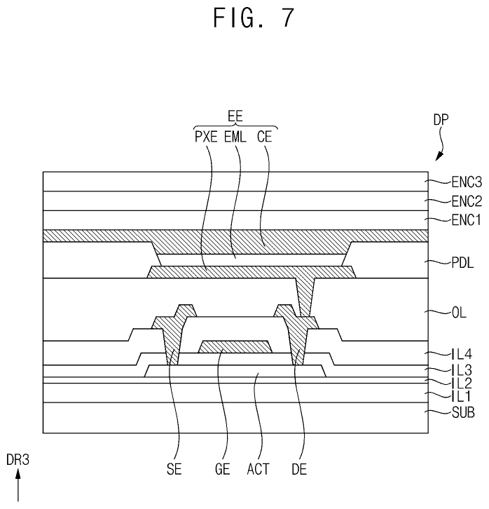

FIG. 6 is a cross-sectional view illustrating an example of a portion of the window module WM of FIG. 2.

Referring to FIG. 6, in the cross-sectional view, the anti-reflective layer AR may be arranged between the base substrate BS and the anti-fingerprint layer AF. In an embodiment, the reflectivity of light reflected from the surface of the window module WM may be about 0.6% or less.

The anti-reflective layer AR may include a first refractive layer L1, a second refractive layer L2, a third refractive layer L3, a fourth refractive layer L4, a fifth refractive layer L5, a sixth refractive layer L6, a seventh refractive layer L7, an eighth refractive layer L8, and a ninth refractive layer L9. In the present disclosure, the first refractive layer L1 may be referred to as the first refractive layer, the second refractive layer L2 as the second refractive layer, the eighth refractive layer L8 as the third refractive layer, the fifth refractive layer L5 as the fourth refractive layer, and the ninth refractive layer L9 as the fifth refractive layer.

In an embodiment, the anti-reflective layer AR may have a structure in which a low-refractive-index layer having a relatively low refractive index and a high-refractive-index layer having a relatively high refractive index are alternately stacked. For example, each of the first refractive layer L1, the third refractive layer L3, the fifth refractive layer L5, the seventh refractive layer L7, and the ninth refractive layer L9 may be the low-refractive-index layer. In addition, each of the second refractive layer L2, the fourth refractive layer L4, the sixth refractive layer L6, and the eighth refractive layer L8 may be the high-refractive-index layer.

In an embodiment, each of the first refractive layer L1, the third refractive layer L3, the fifth refractive layer L5, the seventh refractive layer L7, and the ninth refractive layer L9 may have a refractive index of about 1.8 or less at a wavelength of 550 nm. Suitably, each of the first refractive layer L1, the third refractive layer L3, the fifth refractive layer L5, the seventh refractive layer L7, and the ninth refractive layer L9 may have a refractive index in the range of about 1.35 to about 1.8 at a wavelength of about 550 nm.

In an embodiment, each of the second refractive layer L2, the fourth refractive layer L4, the sixth refractive layer L6, and the eighth refractive layer L8 may have a refractive index of about 1.9 or more at a wavelength of 550 nm. Suitably, each of the second refractive layer L2, the fourth refractive layer L4, the sixth refractive layer L6, and the eighth refractive layer L8 may have a refractive index in the range of about 1.9 to about 2.5 at a wavelength of about 550 nm.

In an embodiment, each of the first refractive layer L1, the third refractive layer L3, the fifth refractive layer L5, the seventh refractive layer L7, and the ninth refractive layer L9 may include silicon oxide (SiOₓ), silicon oxynitride (SiON), or the like. These may be used alone or in combination. In an embodiment, a refractive index of a low-refractive-index layer including silicon oxide (SiOₓ) may be less than a refractive index of a low-refractive-index layer including silicon oxynitride (SiON). However, the materials included in the first, third, fifth, seventh, and ninth refractive layers L1, L3, L5, L7, and L9 according to embodiments of the present disclosure may not be limited thereto.

In an embodiment, each of the second refractive layer L2, the fourth refractive layer L4, the sixth refractive layer L6, and the eighth refractive layer L8 may include silicon nitride (SiNₓ). However, the materials included in the second, fourth, sixth, and eighth refractive layers L2, L4, L6, and L8 according to embodiments of the present disclosure may not be limited thereto.

The first refractive layer L1 may be arranged under the anti-fingerprint layer AF. In an embodiment, a first thickness TH1 of the first refractive layer L1 may be about 70 nm to about 120 nm.

The second refractive layer L2 may be arranged under the first refractive layer L1. In an embodiment, a second thickness TH2 of the second refractive layer L2 may be less than the first thickness TH1 of the first refractive layer L1. For example, the second thickness TH2 may be greater than a value obtained by multiplying the first thickness TH1 by 0.4 and less than the first thickness TH1.

The third refractive layer L3 may be arranged under the second refractive layer L2. The fourth refractive layer L4 may be arranged under the third refractive layer L3. In an embodiment, the thickness of the third refractive layer L3 may be less than the second thickness TH2 of the second refractive layer L2.

The fifth refractive layer L5 may be arranged under the fourth refractive layer L4. In an embodiment, a third thickness TH3 of the fifth refractive layer L5 may be about 50 nm or more.

The sixth refractive layer L6 may be arranged under the fifth refractive layer L5. In an embodiment, the thickness of the sixth refractive layer L6 may be less than the third thickness TH3 of the fifth refractive layer L5.

The seventh refractive layer L7 may be arranged under the sixth refractive layer L6. The eighth refractive layer L8 may be arranged under the seventh refractive layer L7. In an embodiment, a fourth thickness TH4 of the eighth refractive layer L8 may be about 100 nm or more.

In an embodiment, the fourth thickness TH4 of the eighth refractive layer L8 may be greater than the thicknesses of each of the second refractive layer L2, the fourth refractive layer L4, and the sixth refractive layer L6. In other words, the fourth thickness TH4 of the eighth refractive layer L8 may be the greatest among the thicknesses of the high-refractive-index layers included in the anti-reflective layer AR.

The ninth refractive layer L9 may be arranged under the eighth refractive layer L8. In an embodiment, a fifth thickness TH5 of the ninth refractive layer L9 may be about 20 nm or more. In an embodiment, the ninth refractive layer L9 may have a single-layer structure formed of one low-refractive-index layer.

As described above, in the window module WM, the anti-reflective layer AR may have a structure in which low-refractive-index layers and high-refractive-index layers are alternately stacked. In addition, the first thickness TH1 of the first refractive layer L1, which is the uppermost low-refractive-index layer in the anti-reflective layer AR, may be about 70 nm to about 120 nm. In addition, the second thickness TH2 of the second refractive layer L2, which is a high-refractive-index layer arranged under the first refractive layer L1, may be greater than a value obtained by multiplying the first thickness TH1 of the first refractive layer L1 by about 0.4 and less than the first thickness TH1. In addition, the third thickness TH3 of the fifth refractive layer L5, which is the third low-refractive-index layer from the top in the anti-reflective layer AR, may be about 50 nm or more. The fourth thickness TH4 of the eighth refractive layer L8, which is the lowermost high-refractive-index layer included in the anti-reflective layer AR, may be the greatest among the thicknesses of the high-refractive-index layers. In addition, the fifth thickness TH5 of the ninth refractive layer L9, which is the lowermost of the low-refractive-index layers included in the anti-reflective layer AR, may be about 20 nm or more. Accordingly, a color difference generated between light observed from the planar area PA and light observed from the curved area CA of the window module WM may be reduced. In addition, the reflectivity of light reflected from the surface of the window module WM may be reduced.

In addition, in the display device DD of FIG. 1, since the window module WM is included, surface reflectivity may be reduced, and an image with improved display quality may be provided to the user.

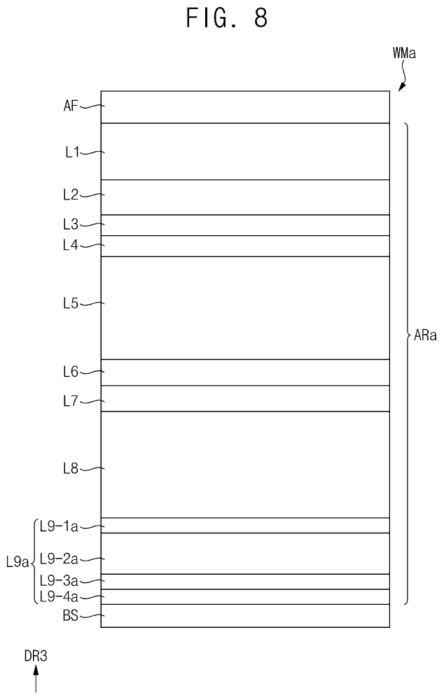

FIG. 7 is a cross-sectional view illustrating a portion of the display panel DP of FIG. 2.

Referring to FIG. 7, the display panel DP may include a substrate SUB, a first insulating layer IL1, a second insulating layer IL2, an active pattern ACT, a third insulating layer IL3, a gate electrode GE, a fourth insulating layer IL4, a source electrode SE, a drain electrode DE, an organic insulating layer OL, a light-emitting element EE, a pixel defining layer PDL, a first encapsulation layer ENC1, a second encapsulation layer ENC2, and a third encapsulation layer ENC3. The light-emitting element EE may include a pixel electrode PXE, a light-emitting layer EML, and a common electrode CE.

The substrate SUB may serve as a base of the display panel DP. The substrate SUB may include a transparent or opaque material. In an embodiment, the substrate SUB may include glass, quartz, plastic, and the like. These may be used alone or in combination.

The first insulating layer IL1 may be arranged on the substrate SUB. The first insulating layer IL1 may prevent metal atoms or impurities from diffusing from the substrate SUB into the active pattern ACT. In addition, the first insulating layer IL1 may control the rate of heat delivery during a crystallization process for forming the active pattern ACT. In an embodiment, the first insulating layer IL1 may include an inorganic insulating material. For example, the insulating material may include silicon nitride (SiNₓ), silicon oxide (SiOₓ), or silicon oxynitride (SiON). These may be used alone or in combination.

The second insulating layer IL2 may be arranged on the first insulating layer IL1. For example, the second insulating layer IL2 may cover an upper surface of the first insulating layer IL1. In an embodiment, the second insulating layer IL2 may include an inorganic insulating material.

The active pattern ACT may be arranged on the second insulating layer IL2. The active pattern ACT may include a source area electrically connected to the source electrode SE, a drain area electrically connected to the drain electrode DE, and a channel area arranged between the source area and the drain area. In an embodiment, the active pattern ACT may include amorphous silicon, polycrystalline silicon, or an oxide semiconductor. These may be used alone or in combination.

The third insulating layer IL3 may be arranged on the active pattern ACT. For example, the third insulating layer IL3 may cover an upper surface of the active pattern ACT. Specifically, the third insulating layer IL3 may have a substantially uniform thickness following the profile of the active pattern ACT. However, according to embodiments of the present disclosure, the third insulating layer IL3 may have a substantially flat upper surface without creating a step around the active pattern ACT. In an embodiment, the third insulating layer IL3 may include an inorganic insulating material.

The gate electrode GE may be arranged on the third insulating layer IL3. The gate electrode GE may overlap with the active pattern ACT in a plan view. For example, the channel area of the active pattern ACT may be defined as a portion of the active pattern ACT overlapping with the gate electrode GE. In an embodiment, the gate electrode GE may include a conductive material.

The fourth insulating layer IL4 may be arranged on the gate electrode GE. For example, the fourth insulating layer IL4 may cover an upper surface of the gate electrode GE. Specifically, the fourth insulating layer IL4 may have a substantially uniform thickness following the profile of the gate electrode GE. However, according to embodiments of the present disclosure, the fourth insulating layer IL4 may have a substantially flat upper surface without creating a step around the gate electrode GE. In an embodiment, the fourth insulating layer IL4 may include an inorganic insulating material.

The source electrode SE and the drain electrode DE may be arranged on the fourth insulating layer IL4. The source electrode SE may be electrically connected to the source area of the active pattern ACT. The drain electrode DE may be electrically connected to the drain area of the active pattern ACT. Specifically, the source electrode SE and the drain electrode DE may contact the active pattern ACT through contact holes that penetrate the third insulating layer IL3 and the fourth insulating layer IL4 in a thickness direction (e.g., the third direction DR3).

The organic insulating layer OL may be arranged on the fourth insulating layer IL4. For example, the organic insulating layer OL may cover the source electrode SE and the drain electrode DE on the fourth insulating layer IL4. In an embodiment, the organic insulating layer OL may include an organic insulating material. For example, the organic insulating material may include polyamide, polysulfone, or the like. These may be used alone or in combination. In an embodiment, the organic insulating layer OL may have a substantially flat upper surface.

The pixel electrode PXE may be arranged on the organic insulating layer OL. The pixel electrode PXE may contact the drain electrode DE through a contact hole penetrating the organic insulating layer OL in the thickness direction (e.g., the third direction DR3). Accordingly, the pixel electrode PXE may be electrically connected to the drain electrode DE. However, according to embodiments of the present disclosure, the pixel electrode PXE may not be limited thereto and may instead be electrically connected to the source electrode SE through the contact hole. In an embodiment, the pixel electrode PXE may include a conductive material.

The pixel defining layer PDL may be arranged on the organic insulating layer OL. The pixel defining layer PDL may partially cover the pixel electrode PXE. For example, a hole may be defined in the pixel defining layer PDL to expose a central portion of the pixel electrode PXE, and the pixel defining layer PDL may cover the edge portion of the pixel electrode PXE. In an embodiment, the pixel defining layer PDL may include an organic insulating material.

The light-emitting layer EML may be arranged on the pixel electrode PXE. For example, the light-emitting layer EML may be disposed on the pixel electrode PXE exposed by the pixel defining layer PDL and the hole of the pixel defining layer PDL. In an embodiment, the light-emitting layer EML may include a light-emitting material. For example, the light-emitting material may include an organic light-emitting material, quantum dots, or the like. These may be used alone or in combination.

The common electrode CE may be arranged on the pixel defining layer PDL. For example, the common electrode CE may be disposed over the pixel defining layer PDL and the light-emitting layer EML. The common electrode CE may include a conductive material. This may be used alone or in combination.

The first encapsulation layer ENC1 may be arranged on the common electrode CE. In an embodiment, the first encapsulation layer ENC1 may include an inorganic insulating material. The second encapsulation layer ENC2 may be arranged on the first encapsulation layer ENC1. In an embodiment, the second encapsulation layer ENC2 may include an organic insulating material. The third encapsulation layer ENC3 may be arranged on the second encapsulation layer ENC2. In an embodiment, the third encapsulation layer ENC3 may include an inorganic insulating material. The first, second, and third encapsulation layers ENC1, ENC2, and ENC3 may block the inflow of moisture or foreign substances into the light-emitting element EE and protect the light-emitting element EE.

However, the structure of the display panel DP according to the embodiments of the present disclosure may not be limited thereto, and the display panel DP may have various structures for emitting light through the light-emitting element EE. For example, the display panel DP may further include at least one conductive layer under the active pattern ACT and/or at least one conductive layer between the drain electrode DE and the pixel electrode PXE in the cross-sectional view.

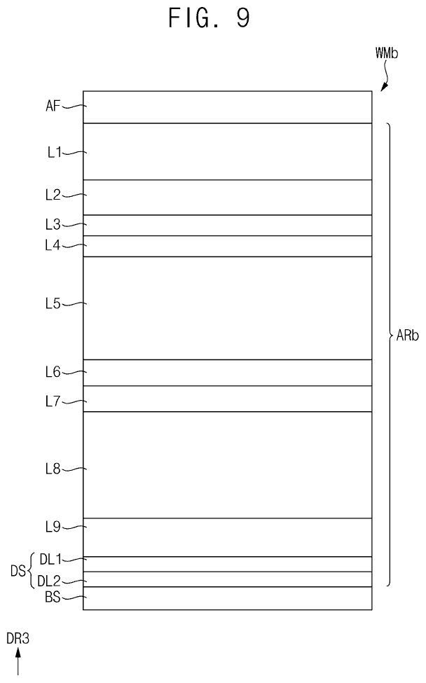

FIG. 8 is a cross-sectional view illustrating an example of a portion of a window module WMa of FIG. 2.

The window module WMa with reference to FIG. 8 may have substantially a same structure as or a similar structure to the window module WM described with reference to FIG. 6, except for a structure of a ninth refractive layer L9a. Hereinafter, overlapping descriptions with the window module WM described with reference to FIG. 6 may be omitted or briefly described.

Referring to FIG. 8, the window module WMa may include an anti-reflective layer ARa. The anti-reflective layer ARa may include the ninth refractive layer L9a. In an embodiment, the ninth refractive layer L9a may have a multi-layered structure formed of a plurality of low-refractive-index layers. For example, the ninth refractive layer L9a may include a first sub-refractive layer L9-1a, a second sub-refractive layer L9-2a, a third sub-refractive layer L9-3a, and a fourth sub-refractive layer L9-4a.

In an embodiment, each of the first sub-refractive layer L9-1a, the second sub-refractive layer L9-2a, the third sub-refractive layer L9-3a, and the fourth sub-refractive layer L9-4a may be the low-refractive-index layer. For example, the first sub-refractive layer L9-1a, the second sub-refractive layer L9-2a, the third sub-refractive layer L9-3a, and the fourth sub-refractive layer L9-4a may each include silicon oxide (SiOₓ), silicon oxynitride (SiON), and the like. These may be used alone or in combination.

In an embodiment, the first sub-refractive layer L9-1a and the third sub-refractive layer L9-3a may include the same material. For example, the first sub-refractive layer L9-1a and the third sub-refractive layer L9-3a may include silicon oxynitride (SiON).

In an embodiment, the second sub-refractive layer L9-2a and the fourth sub-refractive layer L9-4a may include the same material. For example, the second sub-refractive layer L9-2a and the fourth sub-refractive layer L9-4a may include silicon oxide (SiOₓ).

In an embodiment, the first sub-refractive layer L9-1a may include a material different from the second sub-refractive layer L9-2a. In an embodiment, the second sub-refractive layer L9-2a may include a material different from the third sub-refractive layer L9-3a. In an embodiment, the third sub-refractive layer L9-3a may include a material different from the fourth sub-refractive layer L9-4a.

In an embodiment, a refractive index of the first sub-refractive layer L9-1a may be greater than a refractive index of the second sub-refractive layer L9-2a. In an embodiment, the refractive index of the second sub-refractive layer L9-2a may be less than a refractive index of the third sub-refractive layer L9-3a. In an embodiment, the refractive index of the third sub-refractive layer L9-3a may be greater than a refractive index the fourth sub-refractive layer L9-4a.

As described above, in the window module WMa, the anti-reflective layer ARa may have a structure in which low-refractive-index layers and high-refractive-index layers are alternately stacked. In addition, the first thickness of the first refractive layer L1, which is the low-refractive-index layer located at the top of the anti-reflective layer ARa, may be about 70 nm to about 120 nm. In addition, the second thickness of the second refractive layer L2, which is the high-refractive-index layer disposed under the first refractive layer L1, may be greater than a value obtained by multiplying the first thickness of the first refractive layer L1 by 0.4 and less than the first thickness. In addition, the third thickness of the fifth refractive layer L5, which is the low-refractive-index layer located third from the top of the anti-reflective layer ARa among the low-refractive-index layers included in the anti-reflective layer ARa, may be at least about 50 nm. In addition, the fourth thickness of the eighth refractive layer L8, which is the high-refractive-index layer located at the bottom of the anti-reflective layer ARa among the high-refractive-index layers included in the anti-reflective layer ARa, may be the greatest among the thicknesses of the high-refractive-index layers. In addition, the thickness of the ninth refractive layer L9a, which is the low-refractive-index layer located at the bottom of the anti-reflective layer ARa among the low-refractive-index layers included in the anti-reflective layer ARa, may be at least about 20 nm. Accordingly, the color difference generated between light visible from the planar area PA and light visible from the curved area CA of the window module WMa may be reduced. In addition, the reflectivity of light reflected from the surface of the window module WMa may be reduced.

In addition, the ninth refractive layer L9a may have a multi-layered structure in which a plurality of low-refractive-index layers are stacked. Accordingly, the fifth thickness of the ninth refractive layer L9a in FIG. 8 may be greater than the fifth thickness TH5 of the ninth refractive layer L9 in FIG. 6. Therefore, the durability of the window module WMa including the ninth refractive layer L9a may be further improved.

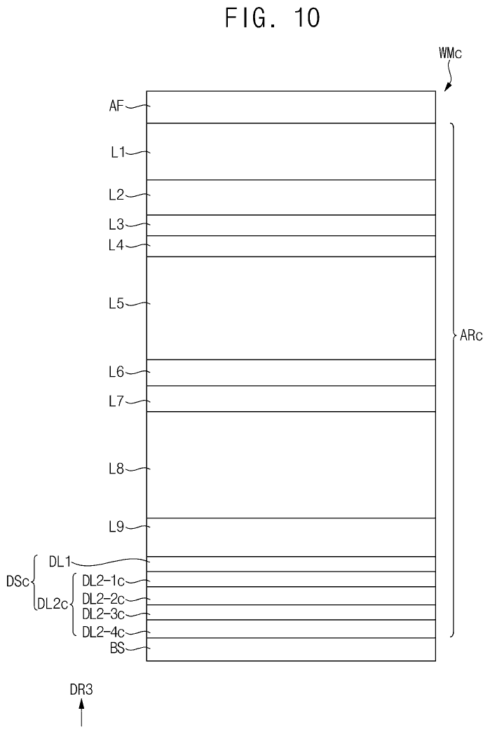

FIG. 9 is a cross-sectional view illustrating an example of a portion of a window module WMb of FIG. 2.

The window module WMb described with reference to FIG. 9 may have substantially a same structure as or a similar structure to the window module WM described with reference to FIG. 6, except that the window module WMb further includes a dummy structure DS. Hereinafter, redundant descriptions overlapping with the window module WM described with reference to FIG. 6 may be omitted or briefly described.

Referring to FIG. 9, the window module WMb may include an anti-reflective layer ARb. The anti-reflective layer ARb may further include the dummy structure DS. In an embodiment, the dummy structure DS may have a multi-layered structure in which low-refractive-index layers and high-refractive-index layers are alternately stacked. For example, the dummy structure DS may further include a first dummy layer DL1 and a second dummy layer DL2.

The first dummy layer DL1 may be disposed under the ninth refractive layer L9. In an embodiment, the first dummy layer DL1 may be a high-refractive-index layer. For example, the first dummy layer DL1 may include silicon nitride (SiNₓ).

The second dummy layer DL2 may be disposed under the first dummy layer DL1. In an embodiment, the second dummy layer DL2 may be a low-refractive-index layer. For example, the second dummy layer DL2 may include silicon oxide (SiOₓ), silicon oxynitride (SiON), and the like.

In an embodiment, the total thickness of the dummy structure DS (e.g., the sum of the thicknesses of the first dummy layer DL1 and the second dummy layer DL2) may be less than the thicknesses of each of the first refractive layer L1, the second refractive layer L2, the third refractive layer L3, the fourth refractive layer L4, the fifth refractive layer L5, the sixth refractive layer L6, the seventh refractive layer L7, the eighth refractive layer L8, and the ninth refractive layer L9. In an embodiment, the thicknesses of the first dummy layer DL1 and the second dummy layer DL2 may be the same. However, the thicknesses of the first dummy layer DL1 and the second dummy layer DL2 according to embodiments of the present disclosure may not be necessarily limited thereto.

As described above, in the window module WMb, the anti-reflective layer ARb may have a structure in which low-refractive-index layers and high-refractive-index layers are alternately stacked. In addition, the first thickness of the first refractive layer L1, which is a low-refractive-index layer located at the top of the anti-reflective layer ARb, may be about 70 nm to about 120 nm. In addition, the second thickness of the second refractive layer L2, which is a high-refractive-index layer disposed under the first refractive layer L1, may be greater than a value obtained by multiplying the first thickness by 0.4 and less than the first thickness. In addition, the third thickness of the fifth refractive layer L5, which is a low-refractive-index layer located third from the top of the anti-reflective layer ARb, may be 50 nm or more. In addition, the fourth thickness of the eighth refractive layer L8, which is a high-refractive-index layer located at the bottommost portion of the high-refractive-index layers included in the anti-reflective layer ARb, may be the greatest among the high-refractive-index layers. In addition, the fifth thickness of the ninth refractive layer L9, which is a low-refractive-index layer located at the bottommost portion of the low-refractive-index layers included in the anti-reflective layer ARb, may be 20 nm or more. Accordingly, the color difference generated between light observed from the planar area PA and light observed from the curved area CA of the window module WMb may be reduced. In addition, the reflectivity of light reflected from the surface of the window module WMb may be reduced.

In addition, the window module WMb may further include the dummy structure DS disposed under the ninth refractive layer L9, in which low-refractive-index layers and high-refractive-index layers are stacked. Accordingly, the total thickness of the anti-reflective layer ARb of FIG. 9 may be greater than the thickness of the anti-reflective layer AR of FIG. 6. Therefore, the durability of the window module WMb including the anti-reflective layer ARb may be improved.

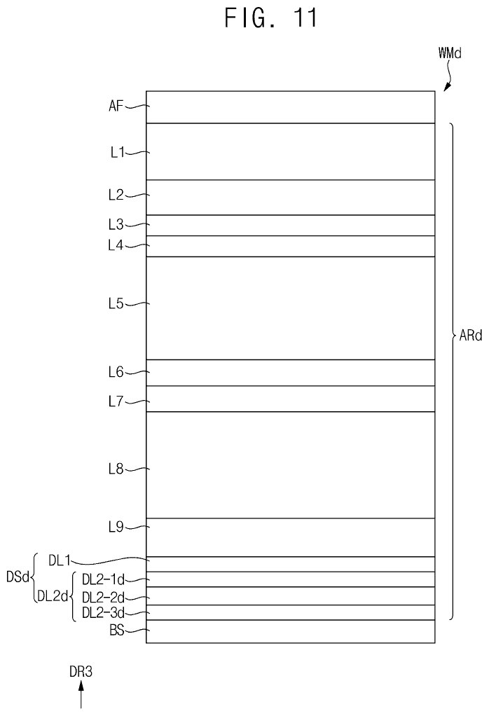

FIG. 10 is a cross-sectional view illustrating an example of a portion of a window module WMc of FIG. 2.

The window module WMc described with reference to FIG. 10 may have a structure substantially same or a similar structure to the window module WMb described with reference to FIG. 9, except that the window module WMc includes a second dummy layer DL2c comprising a plurality of layers. Hereinafter, content overlapping with the window modules WM and WMb described with reference to FIGS. 6, 7, 8, and 9 may be omitted or briefly described.

Referring to FIG. 10, a dummy structure DSc included in the anti-reflective layer ARc of the window module WMc may include a first dummy layer DL1 and the second dummy layer DL2c. In an embodiment, the second dummy layer DL2c may have a multi-layered structure including a plurality of low-refractive-index layers. For example, the second dummy layer DL2c may include a first sub-dummy layer DL2-1c, a second sub-dummy layer DL2-2c, a third sub-dummy layer DL2-3c, and a fourth sub-dummy layer DL2-4c.

The first sub-dummy layer DL2-1c may be arranged under the first dummy layer DL1. In an embodiment, the first sub-dummy layer DL2-1c may be a low-refractive-index layer. For example, the first sub-dummy layer DL2-1c may include silicon oxide (SiOₓ), silicon oxynitride (SiON), and the like. These materials may be used alone or in combination.

The second sub-dummy layer DL2-2c may be arranged under the first sub-dummy layer DL2-1c. In an embodiment, the second sub-dummy layer DL2-2c may be a low-refractive-index layer. For example, the second sub-dummy layer DL2-2c may include silicon oxide (SiOₓ), silicon oxynitride (SiON), and the like. These materials may be used alone or in combination.

The third sub-dummy layer DL2-3c may be arranged under the second sub-dummy layer DL2-2c. In an embodiment, the third sub-dummy layer DL2-3c may be a low-refractive-index layer. For example, the third sub-dummy layer DL2-3c may include silicon oxide (SiOₓ), silicon oxynitride (SiON), and the like. These materials may be used alone or in combination.

The fourth sub-dummy layer DL2-4c may be arranged under the third sub-dummy layer DL2-3c. In an embodiment, the fourth sub-dummy layer DL2-4c may be a low-refractive-index layer. For example, the fourth sub-dummy layer DL2-4c may include silicon oxide (SiOₓ), silicon oxynitride (SiON), and the like. These materials may be used alone or in combination.

In an embodiment, the first sub-dummy layer DL2-1c and the third sub-dummy layer DL2-3c may include the same material. In an embodiment, the second sub-dummy layer DL2-2c and the fourth sub-dummy layer DL2-4c may include the same material. In an embodiment, the first sub-dummy layer DL2-1c and the third sub-dummy layer DL2-3c may include a material different from the second sub-dummy layer DL2-2c and the fourth sub-dummy layer DL2-4c. For example, the first sub-dummy layer DL2-1c and the third sub-dummy layer DL2-3c may include silicon oxynitride (SiON), and the second sub-dummy layer DL2-2c and the fourth sub-dummy layer DL2-4c may include silicon oxide (SiOₓ).

As described above, in the window module WMc, the anti-reflective layer ARc may have a structure in which low-refractive-index layers and high-refractive-index layers are alternately stacked. In addition, a first thickness of the first refractive layer L1, which is the low-refractive-index layer located at the topmost portion of the anti-reflective layer ARc, may be about 70 nm to about 120 nm. In addition, a second thickness of the second refractive layer L2, which is the high-refractive-index layer arranged under the first refractive layer L1, may be greater than a value obtained by multiplying the first thickness by 0.4 and less than the first thickness. In addition, a third thickness of the fifth refractive layer L5, which is the third low-refractive-index layer from the top in the anti-reflective layer ARc, may be about 50 nm or more. In addition, a fourth thickness of the eighth refractive layer L8, which is the lowermost high-refractive-index layer in the anti-reflective layer ARc, may be the largest among the high-refractive-index layers. In addition, a fifth thickness of the ninth refractive layer L9, which is the lowermost low-refractive-index layer in the anti-reflective layer ARc, may be about 20 nm or more. Accordingly, color difference between light visible in the planar area PA of the window module WMc and light visible in the curved area CA of the window module WM may be reduced. In addition, the reflectivity of light reflected from the surface of the window module WMc may be reduced.

In addition, the window module WMc may further include the dummy structure DSc, in which low-refractive-index layers and high-refractive-index layers are stacked, arranged under the ninth refractive layer L9. Accordingly, the total thickness of the anti-reflective layer ARc in FIG. 10 may be greater than the thickness of the anti-reflective layer AR in FIG. 6. In addition, the dummy structure DSc may include the second dummy layer DL2c comprising a plurality of layers. Accordingly, the total thickness of the anti-reflective layer ARc in FIG. 10 may be greater than the thickness of the anti-reflective layer ARb in FIG. 9. Therefore, the durability of the window module WMc including the anti-reflective layer ARc may be further improved.

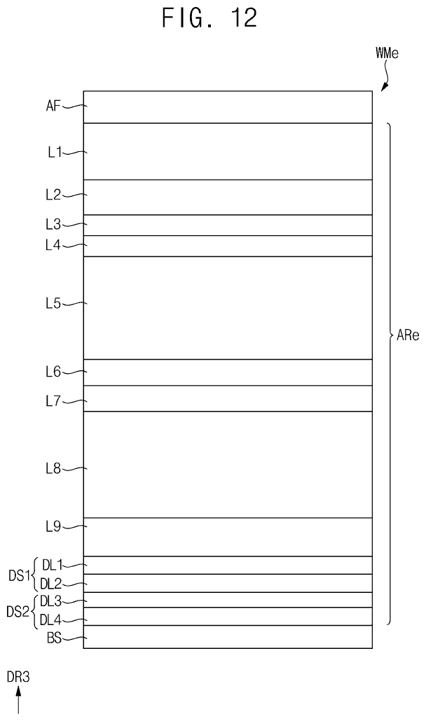

FIG. 11 is a cross-sectional view illustrating an example of a portion of a window module WMd of FIG. 2.

The window module WMd described with reference to FIG. 11 may have substantially a same structure or a similar structure to the window module WMc described with reference to FIG. 10, except that the structure of a second dummy layer DL2d is different. Hereinafter, overlapping descriptions with the window modules WM and WMc described with reference to FIGS. 6 and 9 may be omitted or briefly explained.

Referring to FIG. 11, a dummy structure DSd included in the anti-reflective layer ARd of the window module WMd may include a first dummy layer DL1 and the second dummy layer DL2d. In an embodiment, the second dummy layer DL2d may have a multi-layered structure including a plurality of low-refractive-index layers. For example, the second dummy layer DL2d may include a first sub-dummy layer DL2-1d, a second sub-dummy layer DL2-2d, and a third sub-dummy layer DL2-3d.

The first sub-dummy layer DL2-1d may be arranged under the first dummy layer DL1. In an embodiment, the first sub-dummy layer DL2-1d may be a low-refractive-index layer. For example, the first sub-dummy layer DL2-1d may include silicon oxide (SiOₓ), silicon oxynitride (SiON), and the like. These may be used alone or in combination.

The second sub-dummy layer DL2-2d may be arranged under the first sub-dummy layer DL2-1d. In an embodiment, the second sub-dummy layer DL2-2d may be a low-refractive-index layer. For example, the second sub-dummy layer DL2-2d may include silicon oxide (SiOₓ), silicon oxynitride (SiON), and the like. These may be used alone or in combination.

The third sub-dummy layer DL2-3d may be arranged under the second sub-dummy layer DL2-2d. In an embodiment, the third sub-dummy layer DL2-3d may be a low-refractive-index layer. For example, the third sub-dummy layer DL2-3d may include silicon oxide (SiOₓ), silicon oxynitride (SiON), and the like. These may be used alone or in combination.

In an embodiment, the first sub-dummy layer DL2-1d and the third sub-dummy layer DL2-3d may include the same material. In an embodiment, the first sub-dummy layer DL2-1d and the third sub-dummy layer DL2-3d may include a material different from the second sub-dummy layer DL2-2d. For example, the first sub-dummy layer DL2-1d and the third sub-dummy layer DL2-3d may include silicon oxide (SiOₓ), and the second sub-dummy layer DL2-2d may include silicon oxynitride (SiON).

As described above, in the window module WMd, the anti-reflective layer ARd may have a structure in which low-refractive-index layers and high-refractive-index layers are alternately stacked. In addition, the first thickness of the first refractive layer L1, which is a low-refractive-index layer located at the topmost of the anti-reflective layer ARd, may be about 70 nm to about 120 nm. In addition, the second thickness of the second refractive layer L2, which is a high-refractive-index layer arranged under the first refractive layer L1, may be greater than the value obtained by multiplying the first thickness by 0.4 and less than the first thickness. In addition, the third thickness of the fifth refractive layer L5, which is a low-refractive-index layer located third from the top of the anti-reflective layer ARd, may be at least about 50 nm. In addition, the fourth thickness of the eighth refractive layer L8, which is a high-refractive-index layer located at the bottommost of the anti-reflective layer AR and included among the high-refractive-index layers, may be the greatest among the high-refractive-index layers. In addition, the fifth thickness of the ninth refractive layer L9, which is a low-refractive-index layer located at the bottommost of the anti-reflective layer ARd and included among the low-refractive-index layers, may be at least about 20 nm. Accordingly, the color difference generated between light perceived from the planar area PA of the window module WMd and light perceived from the curved area CA of the window module WM may be reduced. In addition, the reflectivity of light reflected from the surface of the window module WMd may be reduced.

In addition, the window module WMd may further include the dummy structure DSd that is arranged under the ninth refractive layer L9 and has low-refractive-index layers and high-refractive-index layers alternately stacked. Accordingly, the total thickness of the anti-reflective layer ARd of FIG. 11 may be greater than thickness of the anti-reflective layer AR of FIG. 6. In addition, the dummy structure DSd may include the second dummy layer DL2d including a plurality of layers. Accordingly, the total thickness of the anti-reflective layer ARd of FIG. 11 may be greater than the thickness of the anti-reflective layer ARb of FIG. 9. Therefore, the durability of the window module WMd including the anti-reflective layer ARd may be further improved.

In addition, unlike the second dummy layer DL2c of FIG. 10 including four layers, the second dummy layer DL2d of FIG. 11 may include three layers. Accordingly, by forming low-refractive-index layers having various stacked structures, the thickness may be variably controlled, reflectivity, and refractive index of the window module WMd including the anti-reflective layer ARd.

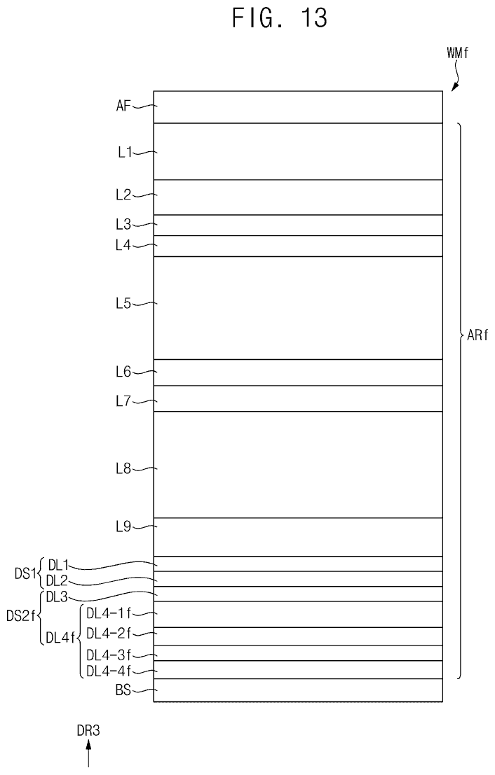

FIG. 12 is a cross-sectional view illustrating an example of a portion of a window module WMe of FIG. 2.

The window module WMe described with reference to FIG. 12 may have substantially a same structure or a similar structure to the window module WMb described with reference to FIG. 9, except for the difference in the number of dummy structures. Hereinafter, overlapping descriptions with the window module WMb described with reference to FIG. 9 may be omitted or briefly explained.

Referring to FIG. 12, the window module WMe may include an anti-reflective layer ARe. The anti-reflective layer ARe may further include a first dummy structure DS1 and a second dummy structure DS2. In an embodiment, each of the first dummy structure DS1 and the second dummy structure DS2 may have a multi-layered structure in which low-refractive-index layers and high-refractive-index layers are alternately stacked. For example, the first dummy structure DS1 may further include a first dummy layer DL1 and a second dummy layer DL2. In addition, the second dummy structure DS2 may include a third dummy layer DL3 and a fourth dummy layer DL4. In an embodiment, each of the first dummy layer DL1, the second dummy layer DL2, the third dummy layer DL3, and the fourth dummy layer DL4 may have a single-layer structure.

The first dummy layer DL1 may be arranged under the ninth refractive layer L9. In an embodiment, the first dummy layer DL1 may be a high-refractive-index layer. For example, the first dummy layer DL1 may include silicon nitride (SiNₓ).

The second dummy layer DL2 may be arranged under the first dummy layer DL1. In an embodiment, the second dummy layer DL2 may be a low-refractive-index layer. For example, the second dummy layer DL2 may include silicon oxide (SiOₓ), silicon oxynitride (SiON), and the like.

The third dummy layer DL3 may be arranged under the second dummy layer DL2. In an embodiment, the third dummy layer DL3 may be a high-refractive-index layer. For example, the first dummy layer DL1 may include silicon nitride (SiNₓ).

The fourth dummy layer DL4 may be arranged under the third dummy layer DL3. In an embodiment, the fourth dummy layer DL4 may be a low-refractive-index layer. For example, the second dummy layer DL2 may include silicon oxide (SiOₓ), silicon oxynitride (SiON), and the like.

As described above, in the window module WMe, the anti-reflective layer ARe may have a structure in which low-refractive-index layers and high-refractive-index layers are alternately stacked. In addition, the first thickness of the first refractive layer L1, which is a low-refractive-index layer located at the topmost of the anti-reflective layer ARe, may be about 70 nm to about 120 nm. In addition, the second thickness of the second refractive layer L2, which is a high-refractive-index layer arranged under the first refractive layer L1, may be greater than the value obtained by multiplying the first thickness by 0.4 and less than the first thickness. In addition, the third thickness of the fifth refractive layer L5, which is a low-refractive-index layer located third from the top of the anti-reflective layer ARe, may be at least about 50 nm. In addition, the fourth thickness of the eighth refractive layer L8, which is a high-refractive-index layer located at the bottommost of the anti-reflective layer ARe among the high-refractive-index layers, may be the greatest among the high-refractive-index layers. In addition, the fifth thickness of the ninth refractive layer L9, which is located at the bottommost of the anti-reflective layer ARe among the low-refractive-index layers, may be at least about 20 nm. Accordingly, the color difference generated between light perceived from the planar area PA and light perceived from the curved area CA of the window module WMe may be reduced. In addition, the reflectivity of light reflected from the surface of the window module WMe may be reduced.

In addition, the window module WMe may further include the first dummy structure DS1 and the second dummy structure DS2, which are arranged under the ninth refractive layer L9 and have stacked low-refractive-index layers and high-refractive-index layers. Accordingly, the total thickness of the anti-reflective layer ARe of FIG. 12 may be greater than the thicknesses of the anti-reflective layers AR and ARb of FIGS. 6 and 9, respectively. Therefore, the durability of the window module WMe including the anti-reflective layer ARe may be further improved.

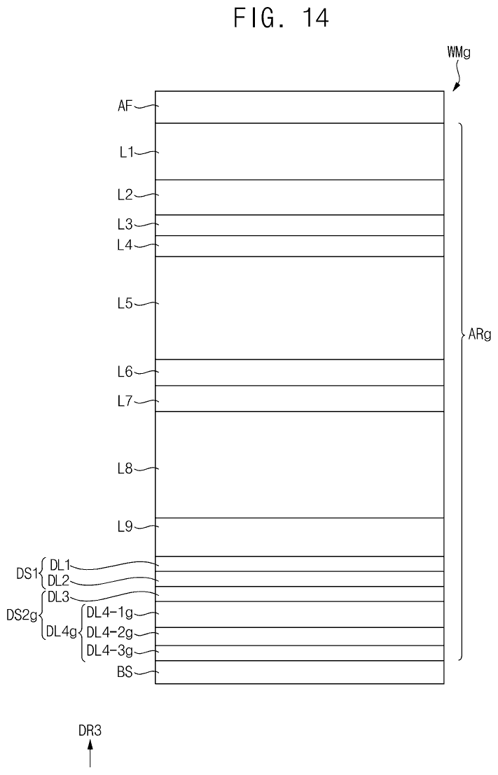

FIG. 13 is a cross-sectional view illustrating an example of a portion of a window module WMf of FIG. 2.

The window module WMf described with reference to FIG. 13 may have substantially a same structure or a similar structure to the window module WMe described with reference to FIG. 12, except for the difference in the structure of the fourth dummy layer DL4f. Hereinafter, overlapping descriptions with the window modules WM and WMe described with reference to FIGS. 6 and 12 may be omitted or briefly explained.

Referring to FIG. 13, the anti-reflective layer ARf of the window module WMf may include the fourth dummy layer DL4f. The fourth dummy layer DL4f may have a multi-layered structure in which a plurality of low-refractive-index layers are stacked. For example, the fourth dummy layer DL4f may include a first sub dummy layer DL4-1f, a second sub dummy layer DL4-2f, a third sub dummy layer DL4-3f, and a fourth sub dummy layer DL4-4f.

The first sub dummy layer DL4-If may be arranged under the third dummy layer DL3. In an embodiment, the first sub dummy layer DL4-1f may be a low-refractive-index layer. For example, the first sub dummy layer DL4-If may include silicon oxide (SiOₓ), silicon oxynitride (SiON), and the like.

The second sub dummy layer DL4-2f may be arranged under the first sub dummy layer DL4-1f. In an embodiment, the second sub dummy layer DL4-2f may be a low-refractive-index layer. For example, the second sub dummy layer DL4-2f may include silicon oxide (SiOₓ), silicon oxynitride (SiON), and the like.

The third sub dummy layer DL4-3f may be arranged under the second sub dummy layer DL4-2f. In an embodiment, the third sub dummy layer DL4-3f may be a low-refractive-index layer. For example, the third sub dummy layer DL4-3f may include silicon oxide (SiOₓ), silicon oxynitride (SiON), and the like.

The fourth sub dummy layer DL4-4f may be arranged under the third sub dummy layer DL4-3f. In an embodiment, the fourth sub dummy layer DL4-4f may be a low-refractive-index layer. For example, the fourth sub dummy layer DL4-4f may include silicon oxide (SiOₓ), silicon oxynitride (SiON), and the like.

In an embodiment, the first sub dummy layer DL4-If and the third sub dummy layer DL4-3f may include the same material. In an embodiment, the second sub dummy layer DL4-2f and the fourth sub dummy layer DL4-4f may include the same material. In an embodiment, the first sub dummy layer DL4-If and the third sub dummy layer DL4-3f may include a material different from the second sub dummy layer DL4-2f and the fourth sub dummy layer DL4-4f. For example, the first and third sub dummy layers DL4-If and DL4-3f may include silicon oxynitride (SiON), and the second and fourth sub dummy layers DL4-2f and DL4-4f may include silicon oxide (SiOₓ). However, the materials included in the first to fourth sub dummy layers DL4-If to DL4-4f according to the embodiments of the present disclosure are not limited thereto.

As described above, in the window module WMf, the anti-reflective layer ARf may have a structure in which low-refractive-index layers and high-refractive-index layers are alternately stacked. In addition, the first thickness of the first refractive layer L1, which is the low-refractive-index layer located at the topmost of the anti-reflective layer ARf, may be about 70 nm to about 120 nm. In addition, the second thickness of the second refractive layer L2, which is the high-refractive-index layer arranged under the first refractive layer L1, may be greater than the value obtained by multiplying the first thickness by 0.4 and less than the first thickness. In addition, the third thickness of the fifth refractive layer L5, which is the low-refractive-index layer located third from the top in the anti-reflective layer ARf, may be at least about 50 nm. In addition, the fourth thickness of the eighth refractive layer L8, which is the high-refractive-index layer located at the bottommost of the anti-reflective layer ARf among the high-refractive-index layers, may be the greatest among the high-refractive-index layers. In addition, the fifth thickness of the ninth refractive layer L9, which is the low-refractive-index layer located at the bottommost of the anti-reflective layer ARf, may be at least about 20 nm. Accordingly, the color difference generated between the light perceived from the planar area PA and the light perceived from the curved area CA of the window module WMf may be reduced. In addition, the reflectivity of light reflected from the surface of the window module WMf may be reduced.

In addition, the window module WMf may further include the first dummy structure DS1 and a second dummy structure DS2f, which are arranged under the ninth refractive layer L9 and have low-refractive-index layers and high-refractive-index layers stacked. Accordingly, the total thickness of the anti-reflective layer ARf of FIG. 13 may be greater than the thicknesses of the anti-reflective layers AR, ARb, and ARe of FIGS. 6, 9, and 12, respectively. Therefore, the durability of the window module WMf including the anti-reflective layer ARf may be further improved.

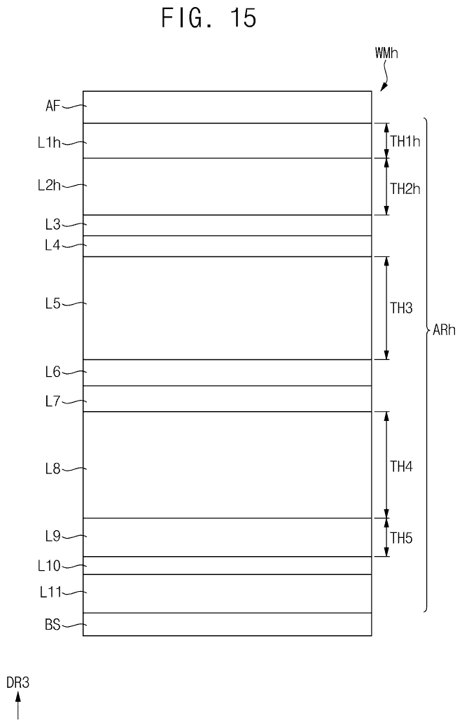

FIG. 14 is a cross-sectional view illustrating an example of a portion of a window module WMg of FIG. 2.

The window module WMg described with reference to FIG. 14 may have substantially a same structure or a similar structure to the window module WMf described with reference to FIG. 13, except for the difference in the structure of the fourth dummy layer DL4g. Hereinafter, overlapping descriptions with the window modules WM, WMe, and WMf described with reference to FIGS. 6, 12, and 13 may be omitted or briefly explained.

Referring to FIG. 14, the anti-reflective layer ARg of the window module WMg may include the fourth dummy layer DL4g. The fourth dummy layer DL4g may have a multi-layered structure in which a plurality of low-refractive-index layers are stacked. For example, the fourth dummy layer DL4g may include a first sub dummy layer DL4-1g, a second sub dummy layer DL4-2g, and a third sub dummy layer DL4-3g.

The first sub dummy layer DL4-1g may be arranged under the third dummy layer DL3. In an embodiment, the first sub dummy layer DL4-1g may be a low-refractive-index layer. For example, the first sub dummy layer DL4-1g may include silicon oxide (SiOₓ), silicon oxynitride (SiON), and the like.

The second sub dummy layer DL4-2g may be arranged under the first sub dummy layer DL4-1g. In an embodiment, the second sub dummy layer DL4-2g may be a low-refractive-index layer. For example, the second sub dummy layer DL4-2g may include silicon oxide (SiOₓ), silicon oxynitride (SiON), and the like.

The third sub dummy layer DL4-3g may be arranged under the second sub dummy layer DL4-2g. In an embodiment, the third sub dummy layer DL4-3g may be a low-refractive-index layer. For example, the third sub dummy layer DL4-3g may include silicon oxide (SiOₓ), silicon oxynitride (SiON), and the like.

In an embodiment, the first sub dummy layer DL4-1g and the third sub dummy layer DL4-3g may include the same material. In an embodiment, the first sub dummy layer DL4-1g and the third sub dummy layer DL4-3g may include a material different from the second sub dummy layer DL4-2g. For example, the first and third sub dummy layers DL4-1g and DL4-3g may include silicon oxide (SiOₓ), and the second sub dummy layer DL4-2g may include silicon oxynitride (SiON). However, the materials included in the first to third sub dummy layers DL4-1g to DL4-3g according to the embodiments of the present disclosure are not limited thereto.

As described above, in the window module WMg, the anti-reflective layer ARg may have a structure in which low-refractive-index layers and high-refractive-index layers are alternately stacked. In addition, the first thickness of the first refractive layer L1, which is the low-refractive-index layer located at the topmost of the anti-reflective layer ARg, may be about 70 nm to about 120 nm. In addition, the second thickness of the second refractive layer L2, which is the high-refractive-index layer arranged under the first refractive layer L1, may be greater than the value obtained by multiplying the first thickness by 0.4 and less than the first thickness. In addition, the third thickness of the fifth refractive layer L5, which is the low-refractive-index layer located third from the top in the anti-reflective layer ARg, may be at least about 50 nm. In addition, the fourth thickness of the eighth refractive layer L8, which is the high-refractive-index layer located at the bottommost of the anti-reflective layer ARg among the high-refractive-index layers, may be the greatest among the high-refractive-index layers. In addition, the fifth thickness of the ninth refractive layer L9, which is the low-refractive-index layer located at the bottommost of the anti-reflective layer ARg, may be at least about 20 nm. Accordingly, the color difference generated between the light perceived from the planar area PA and the light perceived from the curved area CA of the window module WMg may be reduced. In addition, the reflectivity of light reflected from the surface of the window module WMg may be reduced.

In addition, the window module WMg may further include the first dummy structure DS1 and a second dummy structure DS2g, which are arranged under the ninth refractive layer L9 and have low-refractive-index layers and high-refractive-index layers stacked. Accordingly, the total thickness of the anti-reflective layer ARg of FIG. 14 may be greater than the thicknesses of the anti-reflective layers AR and ARb of FIGS. 6 and 9, respectively. Therefore, the durability of the window module WMg including the anti-reflective layer ARg may be further improved.

In addition, unlike the fourth dummy layer DL4f of FIG. 13 which includes four layers, the second dummy layer DL4g of FIG. 14 may include three layers. Accordingly, the thickness, reflectivity, refractive index, and the like of the window module WMg including the anti-reflective layer ARg may be variously adjusted by forming low-refractive-index layers having various stacking structures.

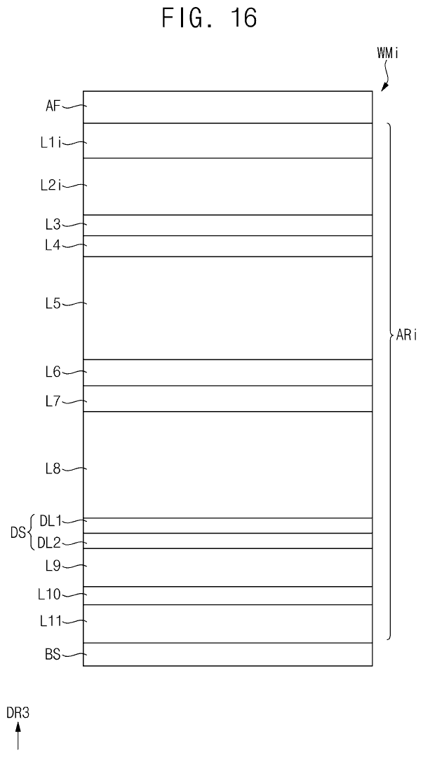

FIG. 15 is a cross-sectional view illustrating an example of a portion of a window module WMh of FIG. 2.

The window module WMh described with reference to FIG. 15 may have substantially a same structure or a similar structure to the window module WM described with reference to FIG. 6, except for including the tenth refractive layer L10 and the eleventh refractive layer L11, and a different thickness relationship between the first refractive layer Llh and the second refractive layer L2h. Hereinafter, overlapping descriptions with the window module WM described with reference to FIG. 6 may be omitted or briefly explained.

Referring to FIG. 15, the window module WMh may include an anti-reflective layer ARh. The anti-reflective layer ARh may include the first refractive layer Llh, the second refractive layer L2h, a third refractive layer L3, a fourth refractive layer L4, a fifth refractive layer L5, a sixth refractive layer L6, a seventh refractive layer L7, an eighth refractive layer L8, a ninth refractive layer L9, the tenth refractive layer L10, and the eleventh refractive layer L11.

In an embodiment, a first thickness TH1h of the first refractive layer Llh may be less than a second thickness TH2h of the second refractive layer L2h. For example, the second thickness TH2h may be greater than the first thickness TH1h and less than a value obtained by multiplying the first thickness TH1h by 1.5.

In an embodiment, the tenth refractive layer L10 may be arranged under the ninth refractive layer L9. In an embodiment, the tenth refractive layer L10 may be a high-refractive-index layer. For example, the tenth refractive layer L10 may include silicon nitride (SiNₓ).

In an embodiment, the eleventh refractive layer L11 may be arranged under the tenth refractive layer L10. In an embodiment, the eleventh refractive layer L11 may be a high-refractive-index layer. For example, the eleventh refractive layer L11 may include silicon oxynitride (SiON), silicon oxide (SiOₓ), and the like.

As described above, in the window module WMh, the anti-reflective layer ARh may have a structure in which low-refractive-index layers and high-refractive-index layers are alternately stacked. In addition, a first thickness TH1h of the first refractive layer Llh, which is the low-refractive-index layer located at the topmost of the anti-reflective layer ARh, may be about 70 nm to about 120 nm. In addition, a second thickness TH2h of the second refractive layer L2h, which is the high-refractive-index layer arranged under the first refractive layer L1h, may be greater than the first thickness TH1h and less than a value obtained by multiplying the first thickness TH1h by 1.5. In addition, a third thickness TH3 of the fifth refractive layer L5, which is the low-refractive-index layer located third from the top in the anti-reflective layer ARh, may be at least about 50 nm. In addition, a fourth thickness TH4 of the eighth refractive layer L8, which is the high-refractive-index layer located second from the bottom in the anti-reflective layer ARh among the high-refractive-index layers, may be the greatest among the high-refractive-index layers. In addition, a fifth thickness TH5 of the ninth refractive layer L9, which is the low-refractive-index layer located second from the bottom in the anti-reflective layer ARh, may be at least about 20 nm. Accordingly, the color difference generated between light perceived from the planar area PA and light perceived from the curved area CA of the window module WMh may be reduced. In addition, the reflectivity of light reflected from the surface of the window module WMh may be reduced.

In addition, the tenth refractive layer L10 and the eleventh refractive layer L11 may be arranged under the ninth refractive layer L9. Accordingly, the total thickness of the anti-reflective layer ARh of FIG. 15 may be greater than the total thickness of the anti-reflective layer AR of FIG. 6. Therefore, the durability of the window module WMh including the anti-reflective layer ARh may be further improved.

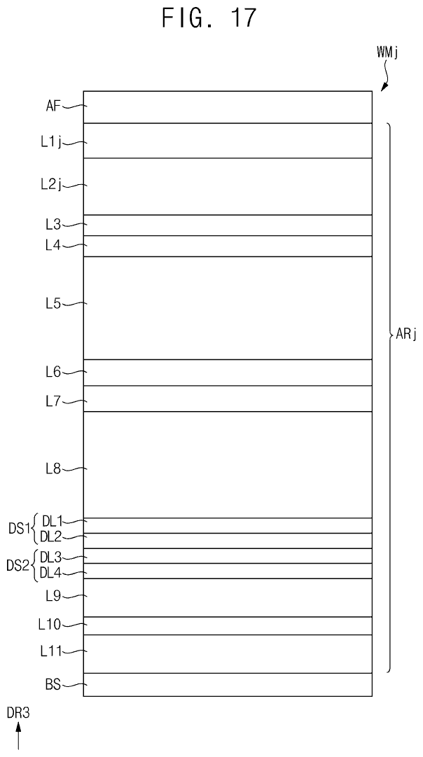

FIG. 16 is a cross-sectional view illustrating an example of a portion of a window module WMi of FIG. 2.

The window module WMi described with reference to FIG. 16 may have substantially a same structure or a similar structure to the window module WMh described with reference to FIG. 15, except for further including a dummy structure DS. Hereinafter, overlapping descriptions with the window module WMh described with reference to FIG. 15 may be omitted or briefly explained.

Referring to FIG. 16, the window module WMi may include an anti-reflective layer ARi. The anti-reflective layer ARi may further include the dummy structure DS. In an embodiment, the dummy structure DS may have a multi-layered structure in which low-refractive-index layers and high-refractive-index layers are alternately stacked. For example, the dummy structure DS may further include a first dummy layer DL1 and a second dummy layer DL2.

The dummy structure DS may be arranged between the eighth refractive layer L8 and the ninth refractive layer L9 in the cross-sectional view. The first dummy layer DL1 may be arranged under the eighth refractive layer L8. In an embodiment, the first dummy layer DL1 may be a low-refractive-index layer. For example, the first dummy layer DL1 may include silicon oxide (SiOₓ), silicon oxynitride (SiON), and the like. The second dummy layer DL2 may be arranged under the first dummy layer DL1. In an embodiment, the second dummy layer DL2 may be a high-refractive-index layer. For example, the second dummy layer DL2 may include silicon nitride (SiNₓ).

As described above, in the window module WMi, the anti-reflective layer ARi may have a structure in which low-refractive-index layers and high-refractive-index layers are alternately stacked. In addition, a first thickness of the first refractive layer L1i, which is a low-refractive-index layer located at the topmost of the anti-reflective layer ARi, may be about 70 nm to about 120 nm. In addition, a second thickness of the second refractive layer L2i, which is a high-refractive-index layer arranged under the first refractive layer L1i, may be greater than the first thickness and less than a value obtained by multiplying the first thickness by 1.5. In addition, a third thickness of the fifth refractive layer L5, which is the low-refractive-index layer located third from the top in the anti-reflective layer ARi, may be at least about 50 nm. In addition, a fourth thickness of the eighth refractive layer L8, which is the high-refractive-index layer located second from the bottom among the high-refractive-index layers in the anti-reflective layer ARi, may be the greatest among the high-refractive-index layers. In addition, a fifth thickness of the ninth refractive layer L9, which is the low-refractive-index layer located second from the bottom among the low-refractive-index layers in the anti-reflective layer ARi, may be at least about 20 nm. Accordingly, the color differences that occur between light perceived from the planar area PA and light perceived from the curved area CA of the window module WMi may be reduced. In addition, the reflectivity of light reflected from the surface of the window module WMi may be reduced.

In addition, the window module WMi may further include the dummy structure DS having stacked low-refractive-index and high-refractive-index layers, which is arranged between the eighth refractive layer L8 and the ninth refractive layer L9 in the cross-sectional view. Accordingly, the total thickness of the anti-reflective layer ARi in FIG. 16 may be greater than the thickness of the anti-reflective layer ARh in FIG. 15. Therefore, the durability of the window module WMi including the anti-reflective layer ARi may be further improved.

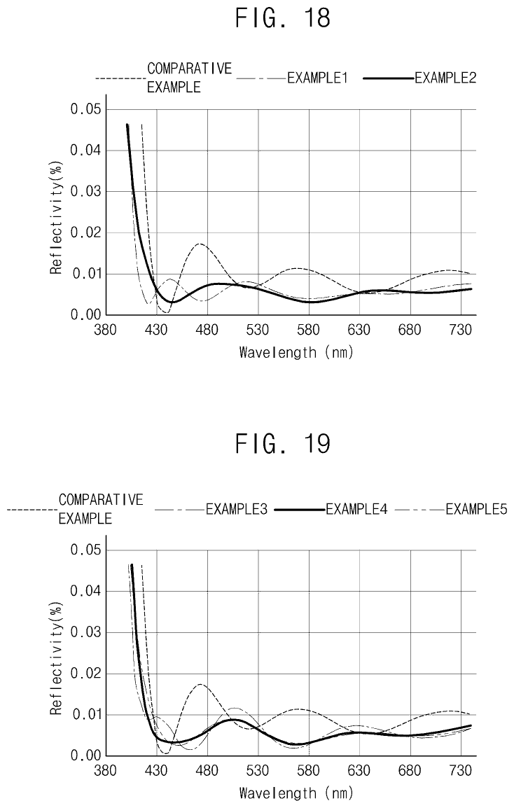

FIG. 17 is a cross-sectional view illustrating an example of a portion of a window module WMj of FIG. 2.

The window module WMj described with reference to FIG. 17 may have substantially a same structure or a similar structure to the window module WMi described with reference to FIG. 16, except for further including a plurality of dummy structures. Hereinafter, overlapping descriptions with the window module WMi described with reference to FIG. 16 may be omitted or briefly explained.

Referring to FIG. 17, the window module WMj may include an anti-reflective layer ARj. The anti-reflective layer ARj may further include a first dummy structure DS1 and a second dummy structure DS2. In an embodiment, each of the first dummy structure DS1 and the second dummy structure DS2 may have a multi-layered structure in which low-refractive-index layers and high-refractive-index layers are alternately stacked. For example, the first dummy structure DS1 may further include a first dummy layer DL1 and a second dummy layer DL2. In addition, the second dummy structure DS2 may further include a third dummy layer DL3 and a fourth dummy layer DL4. In an embodiment, the first dummy structure DS1 and the second dummy structure DS2 may be arranged between the eighth refractive layer L8 and the ninth refractive layer L9 in the cross-sectional view.

The first dummy layer DL1 may be arranged under the eighth refractive layer L8. In an embodiment, the first dummy layer DL1 may be a low-refractive-index layer. For example, the first dummy layer DL1 may include silicon oxide (SiOₓ), silicon oxynitride (SiON), and the like.

The second dummy layer DL2 may be arranged under the first dummy layer DL1. In an embodiment, the second dummy layer DL2 may be a high-refractive-index layer. For example, the second dummy layer DL2 may include silicon nitride (SiNₓ).

The third dummy layer DL3 may be arranged under the second dummy layer DL2. In an embodiment, the third dummy layer DL3 may be a low-refractive-index layer. For example, the third dummy layer DL3 may include silicon oxide (SiOₓ), silicon oxynitride (SiON), and the like.

The fourth dummy layer DL4 may be arranged under the third dummy layer DL3. In an embodiment, the fourth dummy layer DL4 may be a high-refractive-index layer. For example, the fourth dummy layer DL4 may include silicon nitride (SiNₓ).

As described above, in the window module WMj, the anti-reflective layer ARj may have a structure in which low-refractive-index layers and high-refractive-index layers are alternately stacked. In addition, a first thickness of the first refractive layer Llj, which is a low-refractive-index layer located at the topmost of the anti-reflective layer ARj, may be about 70 nm to about 120 nm. In addition, a second thickness of the second refractive layer L2j, which is a high-refractive-index layer arranged under the first refractive layer Llj, may be greater than the first thickness and less than a value obtained by multiplying the first thickness by 1.5. In addition, a third thickness of the fifth refractive layer L5, which is the low-refractive-index layer located third from the top in the anti-reflective layer ARj, may be at least about 50 nm. In addition, a fourth thickness of the eighth refractive layer L8, which is the high-refractive-index layer located second from the bottom among the high-refractive-index layers in the anti-reflective layer ARj, may be the greatest among the high-refractive-index layers. In addition, a fifth thickness of the ninth refractive layer L9, which is the low-refractive-index layer located second from the bottom among the low-refractive-index layers in the anti-reflective layer ARj, may be at least about 20 nm. Accordingly, the color differences that occur between light perceived from the planar area PA and light perceived from the curved area CA of the window module WMj may be reduced. In addition, the reflectivity of light reflected from the surface of the window module WMj may be reduced.

In addition, the window module WMj may further include the first dummy structure DS1 and the second dummy structure DS2 having stacked low-refractive-index and high-refractive-index layers, which are arranged between the eighth refractive layer L8 and the ninth refractive layer L9 in the cross-sectional view. Accordingly, the total thickness of the anti-reflective layer ARj in FIG. 17 may be greater than the total thicknesses of the anti-reflective layer ARh in FIG. 15 and the anti-reflective layer ARi in FIG. 16. Therefore, the durability of the window module WMj including the anti-reflective layer ARj may be further improved.

Hereinafter, the effects of the window module and display device of the present disclosure according to comparative examples and embodiments (e.g., the window module WM in FIG. 2 and the display device DD in FIG. 1) will be described.

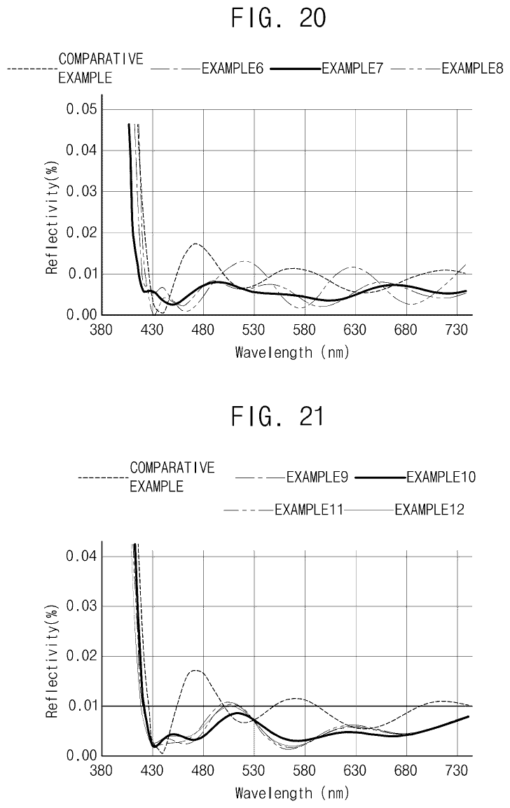

FIGS. 18, 19, 20, and 21 are views for explaining effects of the window module according to embodiments of the present disclosure.

Referring to FIGS. 18, 19, 20, and 21, a window module according to a [comparative example] was manufactured, which includes a base substrate, an anti-fingerprint layer, and an anti-reflective layer in which eleven refractive layers are stacked between the base substrate and the anti-fingerprint layer. The anti-reflective layer of the comparative example was formed to have a structure as shown in Table 1 below.

TABLE 1

| number of refractive layers | material | thickness(nm) |
|---|---|---|
| first refractive layer | SiO₂ | 99.1 |
| second refractive layer | Si₃N₄ | 53.0 |
| third refractive layer | SiO₂ | 8.5 |
| fourth refractive layer | Si₃N₄ | 91.3 |
| fifth refractive layer | SiO₂ | 20.7 |
| sixth refractive layer | Si₃N₄ | 51.0 |
| seventh refractive layer | SiO₂ | 11.5 |
| eighth refractive layer | Si₃N₄ | 137.0 |
| ninth refractive layer | SiO₂ | 28.1 |
| tenth refractive layer | Si₃N₄ | 24.8 |
| eleventh refractive layer | SiO₂ | 8.6 |

The first, second, third, fourth, fifth, sixth, seventh, eighth, ninth, tenth, and eleventh refractive layers were sequentially stacked in a direction from the anti-fingerprint layer toward the base substrate. Specifically, in the window module according to the comparative example, the refractive layer closest to the anti-fingerprint layer is the first refractive layer, and the refractive layer closest to the base substrate is the eleventh refractive layer.

The odd-numbered refractive layers (e.g., the first, third, fifth, seventh, ninth, and eleventh refractive layers) are low-refractive-index layers composed of SiO₂. The even-numbered refractive layers (e.g., the second, fourth, sixth, eighth, and tenth refractive layers) are high-refractive-index layers composed of Si₃N₄. Here, the refractive index of the SiO₂ layer is 1.47, and the refractive index of the Si₃N₄ layer is 2.04.

A window module according to [Example 1] was manufactured, which includes a base substrate, an anti-fingerprint layer, and an anti-reflective layer in which nine refractive layers are stacked between the base substrate and the anti-fingerprint layer. In addition, a window module according to [Example 2] was manufactured, which includes a base substrate, an anti-fingerprint layer, and an anti-reflective layer in which nine refractive layers are stacked between the base substrate and the anti-fingerprint layer, and in which the ninth refractive layer includes four sub-refractive layers. The anti-reflective layers of [Example 1] and [Example 2] were formed to have a structure as shown in Table 2 below.

TABLE 2

| | Example 1 | | Example 2 | |
|---|---|---|---|---|
| | | thickness | | thickness |
| Number of refractive layers | material | (nm) | material | (nm) |
| first refractive layer | SiO₂ | 97.8 | SiO₂ | 95.2 |
| second refractive layer | Si₃N₄ | 60.1 | Si₃N₄ | 87.4 |
| third refractive layer | SiON | 40.4 | SiON | 11.6 |
| fourth refractive layer | Si₃N₄ | 20.6 | Si₃N₄ | 28.3 |
| fifth refractive layer | SiON | 109.9 | SiON | 144.5 |
| sixth refractive layer | Si₃N₄ | 28.7 | Si₃N₄ | 12.4 |
| seventh refractive layer | SiON | 16.2 | SiON | 37.6 |
| eighth refractive layer | Si₃N₄ | 161.7 | Si₃N₄ | 131.0 |
| ninth refractive layer | SiON | 36.7 | including first, second, third, and | |
| | | | fourth sub-refractive layers | |
| first sub-refractive layer | — | — | SiON | 56.8 |
| second sub-refractive layer | — | — | SiO₂ | 170.6 |
| third sub-refractive layer | — | — | SiON | 31.1 |
| fourth sub-refractive layer | — | — | SiO₂ | 21.0 |

The first, second, third, fourth, fifth, sixth, seventh, eighth, and ninth refractive layers were sequentially stacked in a direction from the anti-fingerprint layer toward the base substrate. Specifically, in the window modules according to [Example 1] and [Example 2], the refractive layer closest to the anti-fingerprint layer is the first refractive layer, and the refractive layer closest to the base substrate is the ninth refractive layer.

In addition, the ninth refractive layer according to [Example 2] includes first to fourth sub-refractive layers. The first to fourth sub-refractive layers were sequentially stacked in a direction from the anti-fingerprint layer toward the base substrate. Specifically, in the window module according to [Example 2], the sub-refractive layer closest to the eighth refractive layer is the first sub-refractive layer, and the sub-refractive layer closest to the base substrate is the fourth sub-refractive layer. Here, the refractive index of the SiO₂ layer is 1.47, the refractive index of the SiON layer is 1.7, and the refractive index of the Si₃N₄ layer is 2.04.

A window module according to [Example 3] was manufactured, which includes a base substrate, an anti-fingerprint layer, and an anti-reflective layer including nine refractive layers stacked between the base substrate and the anti-fingerprint layer, and a dummy structure in which a low-refractive-index layer and a high-refractive-index layer are alternately stacked between the lowermost refractive layer and the base substrate. In addition, a window module according to [Example 4] was manufactured based on the structure of [Example 3], in which the low-refractive-index layer of the dummy structure has a multi-layered structure formed of four sub-refractive layers. In addition, a window module according to [Example 5] was manufactured based on the structure of [Example 3], in which the low-refractive-index layer of the dummy structure has a multi-layered structure formed of three sub-refractive layers. The anti-reflective layers according to [Example 3], [Example 4], and [Example 5] were formed to have structures as shown in Table 3 below.

TABLE 3

| | Example 3 | | Example 4 | | Example 5 | |
|---|---|---|---|---|---|---|
| Number of | | thickness | | thickness | | thickness |
| refractive layers | material | (nm) | material | (nm) | material | (nm) |
| first refractive layer | SiO₂ | 94.6 | SiO₂ | 94.4 | SiO₂ | 95.3 |
| second refractive | Si₃N₄ | 65.0 | Si₃N₄ | 65.4 | Si₃N₄ | 64.5 |
| layer | | | | | | |
| third refractive layer | SiON | 8.0 | SiON | 8.0 | SiON | 8.9 |
| fourth refractive | Si₃N₄ | 60.3 | Si₃N₄ | 57.8 | Si₃N₄ | 58.5 |
| layer | | | | | | |
| fifth refractive layer | SiON | 81.2 | SiON | 88.3 | SiON | 84.4 |
| sixth refractive layer | Si₃N₄ | 10.4 | Si₃N₄ | 8.3 | Si₃N₄ | 9.7 |
| seventh refractive | SiON | 60.1 | SiON | 58.0 | SiON | 59.3 |
| layer | | | | | | |
| eighth refractive | Si₃N₄ | 138.8 | Si₃N₄ | 131.3 | Si₃N₄ | 136.7 |
| layer | | | | | | |
| ninth refractive layer | SiON | 56.2 | SiON | 40.7 | SiON | 60.0 |
| dummy structure | A stack of a high-refractive-index layer (top) and at least one | | | | | |
| (below) | low-refractive-index layer (bottom) | | | | | |
| high-refractive-index | Si₃N₄ | 8.0 | Si₃N₄ | 9.9 | Si₃N₄ | 10.9 |
| layer of the dummy | | | | | | |
| structure | | | | | | |
| low-refractive-index | SiON | 8.0 | including four | | including three | |
| layer of the dummy | | | sub-refractive layers | | sub-refractive layers | |
| structure | | | below | | below | |
| first sub-refractive | — | — | SiON | 14.7 | SiO₂ | 64.9 |
| layer | | | | | | |
| second | — | — | SiO₂ | 35.3 | SiON | 17.8 |
| sub-refractive layer | | | | | | |
| third sub-refractive | — | — | SiON | 23.4 | SiO₂ | 48.6 |
| layer | | | | | | |
| fourth sub-refractive | — | — | SiO₂ | 43.8 | — | — |
| layer | | | | | | |

The first, second, third, fourth, fifth, sixth, seventh, eighth, and ninth refractive layers and the dummy structure were sequentially stacked in a direction from the anti-fingerprint layer toward the base substrate. Specifically, in the window modules according to [Example 3], [Example 4], and [Example 5], the refractive layer closest to the anti-fingerprint layer is the first refractive layer, and the layer closest to the base substrate is the dummy structure. The topmost portion of the dummy structure is a high-refractive-index layer, and at least one low-refractive-index layer is disposed between the high-refractive-index layer of the dummy structure and the base substrate.

Specifically, in the window module according to [Example 3], one low-refractive-index layer is disposed between the high-refractive-index layer of the dummy structure and the base substrate. In addition, in the window module according to [Example 4], four low-refractive-index layers, which are four sub-refractive layers, are disposed between the high-refractive-index layer of the dummy structure and the base substrate. Furthermore, in the window module according to [Example 5], three low-refractive-index layers, which are three sub-refractive layers, are disposed between the high-refractive-index layer of the dummy structure and the base substrate. In the window modules according to [Example 4] and [Example 5], the number of sub-refractive layers increases from the high-refractive-index layer of the dummy structure toward the base substrate. In this case, the refractive index of the SiO₂ layer is 1.47, the refractive index of the SiON layer is 1.7, and the refractive index of the Si₃N₄ layer is 2.04.

A window module according to [Example 6], which includes a base substrate, an anti-fingerprint layer, and an anti-reflective layer comprising nine refractive layers disposed between the base substrate and the anti-fingerprint layer, as well as two dummy structures each including stacked low-refractive-index and high-refractive-index layers disposed between the lowermost refractive layer among the refractive layers and the base substrate, was manufactured. In addition, a window module according to [Example 7], which has the same structure as [Example 6] except that the low-refractive-index layer of the lower dummy structure is formed as a multi-layered structure comprising four sub-refractive layers, was manufactured. Furthermore, a window module according to [Example 8], which has the same structure as [Example 6] except that the low-refractive-index layer of the lower dummy structure is formed as a multi-layered structure comprising three sub-refractive layers, was manufactured. The anti-reflective layers according to [Example 6], [Example 7], and [Example 8] were formed to have the structures shown in Table 4 below.

TABLE 4

| | Example 6 | | Example 7 | | Example 8 | |
|---|---|---|---|---|---|---|
| Number of | | thickness | | thickness | | thickness |
| refractive layers | material | (nm) | material | (nm) | material | (nm) |
| first refractive layer | SiO₂ | 97.2 | SiO₂ | 95.8 | SiO₂ | 96.6 |
| second refractive | Si₃N₄ | 65.4 | Si₃N₄ | 63.4 | Si₃N₄ | 57.8 |
| layer | | | | | | |
| third refractive layer | SiON | 8.1 | SiON | 8.0 | SiON | 9.1 |
| fourth refractive | Si₃N₄ | 67.0 | Si₃N₄ | 67.0 | Si₃N₄ | 68.0 |
| layer | | | | | | |
| fifth refractive layer | SiON | 66.4 | SiON | 68.2 | SiON | 96.6 |
| sixth refractive layer | Si₃N₄ | 21.8 | Si₃N₄ | 19.1 | Si₃N₄ | 8.1 |
| seventh refractive | SiON | 51.1 | SiON | 53.7 | SiON | 60.0 |
| layer | | | | | | |
| eighth refractive | Si₃N₄ | 175.7 | Si₃N₄ | 170.5 | Si₃N₄ | 170.2 |
| layer | | | | | | |
| ninth refractive layer | SiON | 20.1 | SiON | 23.0 | SiON | 27.7 |
| first dummy structure | A stack of a high-refractive-index layer (top) and at least one | | | | | |
| (below) | low-refractive-index layer (bottom) | | | | | |
| high-refractive-index | Si₃N₄ | 60.8 | Si₃N₄ | 58.1 | Si₃N₄ | 36.9 |
| layer of the first | | | | | | |
| dummy structure | | | | | | |
| low-refractive-index | SiON | 29.5 | SiON | 27.6 | SiON | 92.1 |
| layer of the first | | | | | | |
| dummy structure | | | | | | |
| second dummy | A stack of a high-refractive-index layer (top) and at least one | | | | | |
| structure (below) | low-refractive-index layer (bottom) | | | | | |
| high-refractive-index | Si₃N₄ | 38.5 | Si₃N₄ | 44.5 | Si₃N₄ | 8.0 |
| layer of the second | | | | | | |
| dummy structure | | | | | | |
| low-refractive-index | SiON | 99.0 | including four | | including three | |
| layer of the second | | | sub-refractive layers | | sub-refractive layers | |
| dummy structure | | | below | | below | |
| first sub-refractive | — | — | SiON | 104.0 | SiO₂ | 236.6 |
| layer | | | | | | |
| second sub-refractive | — | — | SiO₂ | 76.8 | SiON | 17.3 |
| layer | | | | | | |
| third sub-refractive | — | — | SiON | 11.0 | SiO₂ | 43.1 |
| layer | | | | | | |
| fourth sub-refractive | — | — | SiO₂ | 66.8 | — | — |
| layer | | | | | | |

The first second, third, fourth, fifth, sixth, seventh, eighth, and ninth refractive layers, the first dummy structure, and the second dummy structure were sequentially stacked in a direction from the anti-fingerprint layer toward the base substrate. Specifically, in the window modules according to [Example 6], [Example 7], and [Example 8], the refractive layer closest to the anti-fingerprint layer is the first refractive layer, and the layer closest to the base substrate is the second dummy structure. The topmost portion of the first dummy structure is a high-refractive-index layer, and the lowermost portion of the first dummy structure is a low-refractive-index layer. In addition, the topmost portion of the second dummy structure is a high-refractive-index layer, and at least one low-refractive-index layer is disposed between the high-refractive-index layer of the second dummy structure and the base substrate.

Specifically, in the window module according to [Example 6], one low-refractive-index layer is disposed between the high-refractive-index layer of the second dummy structure and the base substrate. In the window module according to [Example 7], four low-refractive-index layers, which are four sub-refractive layers, are disposed between the high-refractive-index layer of the second dummy structure and the base substrate. Furthermore, in the window module according to [Example 8], three low-refractive-index layers, which are three sub-refractive layers, are disposed between the high-refractive-index layer of the second dummy structure and the base substrate. In the window modules according to [Example 7] and [Example 8], the number of sub-refractive layers increases from the high-refractive-index layer of the second dummy structure toward the base substrate. In this case, the refractive index of the SiO₂ layer is 1.47, the refractive index of the SiON layer is 1.7, and the refractive index of the Si₃N₄ layer is 2.04.

A window module according to [Example 9], which includes a base substrate, an anti-fingerprint layer, and an anti-reflective layer comprising 11 refractive layers disposed between the base substrate and the anti-fingerprint layer, was manufactured. In addition, a window module according to [Example 10], which has the same structure as [Example 9] except that one dummy structure comprising stacked low-refractive-index and high-refractive-index layers is disposed between the eighth refractive layer and the ninth refractive layer, counted from the top of the anti-fingerprint layer, was manufactured. Furthermore, window modules according to [Example 11] and [Example 12], which have the same structure as [Example 9] except that two dummy structures comprising stacked low-refractive-index and high-refractive-index layers are disposed between the eighth refractive layer and the ninth refractive layer, counted from the top of the anti-fingerprint layer, were manufactured.

The anti-reflective layers according to [Example 9] and [Example 10] were formed to have the structures shown in Table 5 below. The anti-reflective layers according to [Example 11] and [Example 12] were formed to have the structures shown in Table 6 below.

TABLE 5

| | Example 9 | | Example 10 | |
|---|---|---|---|---|
| Number of refractive | | thickness | | thickness |
| layers | material | (nm) | material | (nm) |
| first refractive layer | SiO₂ | 90.9 | SiO₂ | 91.6 |
| second refractive | Si₃N₄ | 110.3 | Si₃N₄ | 112.1 |
| layer | | | | |
| third refractive layer | SiO₂ | 13.3 | SiON | 12,3 |
| fourth refractive layer | Si₃N₄ | 30.0 | Si₃N₄ | 30.7 |
| fifth refractive layer | SiO₂ | 73.3 | SiON | 67.6 |
| sixth refractive layer | Si₃N₄ | 21.0 | Si₃N₄ | 23.9 |
| seventh refractive | SiO₂ | 53.7 | SiON | 49.5 |
| layer | | | | |
| eighth refractive layer | Si₃N₄ | 155.1 | Si₃N₄ | 149.8 |
| dummy structure | A stack of a low-refractive-index layer (top) and at least one | | | |
| (below) | high-refractive-index layer (bottom) | | | |
| low-refractive-index | — | — | SiO₂ | 17.3 |
| layer of the first | | | | |
| dummy structure | | | | |
| high-refractive-index | — | — | Si₃N₄ | 11.9 |
| layer of the first | | | | |
| dummy structure | | | | |
| ninth refractive layer | SiO₂ | 39.0 | SiO₂ | 34.0 |
| tenth refractive layer | Si₃N₄ | 19.8 | Si₃N₄ | 13.5 |
| eleventh refractive | SiO₂ | 53.7 | SiO₂ | 57.5 |
| layer | | | | |

TABLE 6

| | Example 11 | | Example 12 | |
|---|---|---|---|---|
| Number of refractive | | thickness | | thickness |
| layers | material | (nm) | material | (nm) |
| first refractive layer | SiO₂ | 90.8 | SiO₂ | 90.8 |
| second refractive | Si₃N₄ | 113.8 | Si₃N₄ | 119.5 |
| layer | | | | |
| third refractive layer | SiO₂ | 12.3 | SiON | 14.4 |
| fourth refractive layer | Si₃N₄ | 30.0 | Si₃N₄ | 26.9 |
| fifth refractive layer | SiO₂ | 63.6 | SiON | 60.7 |
| sixth refractive layer | Si₃N₄ | 24.7 | Si₃N₄ | 25.3 |
| seventh refractive | SiO₂ | 48.7 | SiON | 45.9 |
| layer | | | | |
| eighth refractive layer | Si₃N₄ | 147.4 | Si₃N₄ | 146.9 |
| first dummy structure | A stack of a low-refractive-index layer (top) and at least one | | | |
| (below) | high-refractive-index layer (bottom) | | | |
| low-refractive-index | SiO₂ | 15.6 | SiO₂ | 15.2 |
| layer of the first | | | | |
| dummy structure | | | | |
| high-refractive-index | Si₃N₄ | 9.8 | Si₃N₄ | 8.0 |
| layer of the first | | | | |
| dummy structure | | | | |
| second dummy | A stack of a low-refractive-index layer (top) and at least one | | | |
| structure (below) | high-refractive-index layer (bottom) | | | |
| low-refractive-index | SiO₂ | 14.8 | SiO₂ | 13.0 |
| layer of the second | | | | |
| dummy structure | | | | |
| high-refractive-index | Si₃N₄ | 9.4 | Si₃N₄ | 12.5 |
| layer of the second | | | | |
| dummy structure | | | | |
| ninth refractive layer | SiO₂ | 29.9 | SiO₂ | 38.5 |
| tenth refractive layer | Si₃N₄ | 8.3 | Si₃N₄ | 8.0 |
| eleventh refractive | SiO₂ | 60.1 | SiO₂ | 60.2 |
| layer | | | | |

In the anti-reflective layers according to [Example 9] and [Example 10], the first to eighth refractive layers, a dummy structure, and the ninth to eleventh refractive layers were sequentially stacked in a direction from the anti-fingerprint layer toward the base substrate. Specifically, in the window modules according to [Example 9] and [Example 10], the refractive layer closest to the anti-fingerprint layer is the first refractive layer, and the layer closest to the base substrate is the eleventh refractive layer. In addition, the topmost portion of the dummy structure is a low-refractive-index layer, and a high-refractive-index layer is disposed between the low-refractive-index layer of the dummy structure and the ninth refractive layer.

In the anti-reflective layers according to [Example 11] and [Example 12], the first to eighth refractive layers, a first dummy structure, a second dummy structure, and the ninth to eleventh refractive layers were sequentially stacked in a direction from the anti-fingerprint layer toward the base substrate. Specifically, in the window modules according to [Example 11] and [Example 12], the refractive layer closest to the anti-fingerprint layer is the first refractive layer, and the layer closest to the base substrate is the eleventh refractive layer. In addition, the first dummy structure is disposed under the eighth refractive layer, and the second dummy structure is disposed under the first dummy structure. The topmost portion of the first dummy structure is a low-refractive-index layer, and a high-refractive-index layer is disposed between the low-refractive-index layer of the first dummy structure and the second dummy structure. Furthermore, the topmost portion of the second dummy structure is a low-refractive-index layer, and a high-refractive-index layer is disposed between the low-refractive-index layer of the second dummy structure and the ninth refractive layer. In this case, the refractive index of the SiO₂ layer is 1.47, and the refractive index of the Si₃N₄ layer is 2.04.

The total thicknesses of the anti-reflective layers according to the [Comparative Example] and [Examples 1, 2, 3, 4, 5, 6, 7, 8, 9, 10, 11, and 12] are shown in Table 7 below.

TABLE 7

| | Total thickness of anti-reflective layer(nm) |
|---|---|
| Comparative example | 533.6 |
| example 1 | 572.1 |
| example 2 | 827.5 |
| example 3 | 590.6 |
| example 4 | 679.3 |
| example 5 | 719.5 |
| example 6 | 800.6 |
| example 7 | 957.5 |
| example 8 | 1028.1 |
| example 9 | 660.1 |
| example 10 | 671.7 |
| example 11 | 679.2 |
| example 12 | 685.8 |

According to the [Comparative Example] and [Examples 1, 2, 3, 4, 5, 6, 7, 8, 9, 10, 11, and 12], the chroma, color difference, and cross-sectional reflectivity of the window modules including the anti-reflective layer were measured. Specifically, the reflectivity and chroma in the planar area of the window modules according to the [Comparative Example] and [Examples 1, 2, 3, 4, 5, 6, 7, 8, 9, 10, 11, and 12] are shown in Table 8 below. In addition, the color difference in the curved area of the window modules according to the [Comparative Example] and [Examples 1, 2, 3, 4, 5, 6, 7, 8, 9, 10, 11, and 12] is shown in Table 9 below. Specifically, a* indicates the color coordinate value in the red and green directions, and b* indicates the color coordinate value in the yellow and blue directions. The color difference Cis the square root of the sum of the squares of the changes in a* and b*. θ represents the angle between the normal vector in the curved area and the normal vector in the planar area of the window modules according to the [Comparative Example] and the Examples.

TABLE 8

| | reflectivity(%) | a* | b* |
|---|---|---|---|
| Comparative example | 0.93 | 0.00 | −1.23 |
| example 1 | 0.55 | −0.40 | −0.94 |
| example 2 | 0.50 | −0.40 | −1.05 |
| example 3 | 0.55 | −0.40 | −0.79 |
| example 4 | 0.51 | −0.40 | −0.86 |
| example 5 | 0.52 | −0.40 | −1.00 |
| example 6 | 0.56 | −0.40 | −1.39 |
| example 7 | 0.52 | −0.40 | −0.81 |
| example 8 | 0.75 | −0.41 | −0.69 |
| example 9 | 0.48 | −0.39 | −1.01 |
| example 10 | 0.50 | −0.37 | −1.16 |
| example 11 | 0.48 | −0.38 | −0.95 |
| example 12 | 0.48 | −0.40 | −1.05 |

TABLE 9

| θ | 5° | 10° | 15° | 20° | 25° | 30° | 35° | 40° | 45° |
|---|---|---|---|---|---|---|---|---|---|
| Comparative | 2.0 | 2.4 | 4.3 | 4.9 | 4.0 | 3.2 | 3.3 | 3.2 | 3.0 |
| example | | | | | | | | | |
| example 1 | 1.9 | 1.6 | 1.0 | 0.5 | 1.6 | 3.0 | 2.9 | 3.0 | 3.0 |
| example 2 | 2.1 | 1.8 | 2.0 | 3.4 | 4.0 | 2.6 | 1.7 | 3.2 | 3.0 |
| example 3 | 1.4 | 0.5 | 1.3 | 3.0 | 4.0 | 2.6 | 1.6 | 3.0 | 3.0 |
| example 4 | 1.6 | 1.1 | 1.2 | 2.8 | 4.0 | 3.0 | 2.4 | 3.0 | 3.0 |
| example 5 | 2.0 | 1.4 | 1.2 | 2.8 | 4.0 | 3.0 | 1.7 | 3.0 | 3.0 |
| example 6 | 3.2 | 2.3 | 1.2 | 1.9 | 4.0 | 2.9 | 0.7 | 3.0 | 3.0 |
| example 7 | 1.8 | 1.4 | 0.8 | 2.3 | 4.0 | 2.9 | 1.9 | 3.0 | 3.0 |
| example 8 | 1.7 | 2.8 | 3.0 | 1.7 | 1.4 | 3.0 | 3.0 | 2.9 | 3.0 |
| example 9 | 1.2 | 3.3 | 4.9 | 3.7 | 2.9 | 3.7 | 3.9 | 1.2 | 3.3 |
| example 10 | 1.1 | 1.1 | 2.9 | 3.7 | 3.4 | 3.1 | 4.1 | 1.1 | 1.1 |
| example 11 | 2.0 | 4.3 | 5.6 | 3.8 | 3.0 | 3.7 | 3.8 | 2.0 | 4.3 |
| example 12 | 2.0 | 4.0 | 5.2 | 3.8 | 2.9 | 3.8 | 3.8 | 2.0 | 4.0 |

Referring to Table 1, the thickness of the fifth refractive layer in the anti-reflective layer according to the [Comparative Example] is less than 50 nm, whereas, referring to Tables 2, 3, 4, 5, and 6, the thickness of the fifth refractive layer in the anti-reflective layers of each of the window modules according to [Examples 1, 2, 3, 4, 5, 6, 7, 8, 9, 10, 11, and 12] which is 50 nm or more was confirmed.

Referring to Tables 8 and 9, the reflectivity of each of the window modules according to [Examples 1, 2, 3, 4, 5, 6, 7, 8, 9, 10, 11, and 12] lower than the reflectivity of the window module according to the [Comparative Example] was confirmed. The reflectivity of each of the window modules according to [Examples 1, 2, 3, 4, 5, 6, 7, 8, 9, 10, 11, and 12] is 0.75 or less, whereas the reflectivity of the window module according to the [Comparative Example] is 0.93. In addition, although the reflectivity around the 480 nm wavelength in the window module according to the [Comparative Example] is close to 0.02, the reflectivity of each of the window modules according to [Examples 1, 2, 3, 4, 5, 6, 7, 8, 9, 10, 11, and 12] remains relatively uniform around 0.01 across different wavelengths. Accordingly, relatively low reflectivity of the window modules according to the embodiments of the present disclosure was confirmed.

In addition, the total thickness of each of the anti-reflective layers according to [Examples 1, 2, 3, 4, 5, 6, 7, 8, 9, 10, 11, and 12] greater than the thickness of the anti-reflective layer according to the [Comparative Example] was confirmed. Accordingly, since the total thickness of the window module including the anti-reflective layer according to the embodiments of the present disclosure increases, improved durability may be confirmed.

In addition, the color difference of each of the window modules according to [Examples 1, 2, 3, 4, 5, 6, 7, and 8] which is 4.0 or less was confirmed. Each of the window modules according to [Examples 1, 2, 3, 4, 5, 6, 7, 8, 9, 10, 11, and 12] may be manufactured to implement a relatively low color difference depending on θ.

The display device according to an embodiment (e.g., the display device DD of FIG. 1) may be applied to various electronic devices. An electronic device according to an embodiment includes the above-described display device and may further include modules or devices having additional functions besides the display device.

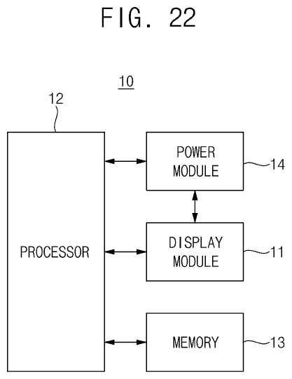

FIG. 22 is a block diagram of an electronic device 10 according to an embodiment of the present disclosure.

Referring to FIG. 22, the electronic device 10 according to an embodiment of the present disclosure may include a display module 11, a processor 12, a memory 13, and a power module 14.

The processor 12 may include one or more processors and may include at least one of a central processing unit CPU, an application processor AP, a graphic processing unit GPU, a communication processor CP, an image signal processor ISP, or a controller.

The memory 13 may store data information required for the operation of the processor 12 or the display module 11. When the processor 12 executes an application stored in the memory 13, image data signals and/or input control signals may be delivered to the display module 11, and the display module 11 may process the received signals to output image information through a display screen.

The power module 14 may include a power supply module such as a power adapter or a battery device, and a power conversion module that converts the power supplied by the power supply module to generate power required for the operation of the electronic device 10.

At least one of the components of the electronic device 10 described above may be included in the display device according to the above-described embodiments (for example, the display device DD of FIG. 1). In addition, among the individual modules functionally included in one module, some may be included in the display device, and others may be provided separately from the display device. For example, the display device may include the display module 11, and the processor 12, memory 13, and power module 14 may be provided in the form of other devices within the electronic device 10, rather than in the display device. For example, the power module 14 may supply power to the display device including the display module 11.

In an embodiment, since the electronic device 10 includes the display device, the electronic device 10 may include the window modules WM, WMa, WMb, WMc, WMd, WMe, WMf, WMg, WMh, WMi, and WMj according to the embodiments of the present disclosure described with reference to FIG. 6 and FIGS. 8, 9, 10, 11, 12, 13, 14, 15, 16, and 17. Accordingly, since the electronic device 10 includes the display device that includes the window modules, surface reflectivity may be reduced, image quality provided to the user may be improved, and images may be stably displayed.

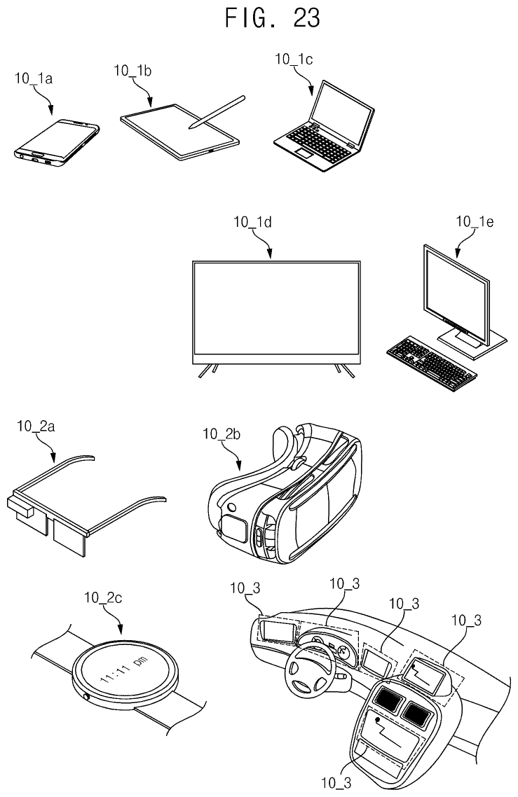

FIG. 23 is a schematic view of electronic devices according to various embodiments.

Referring to FIG. 23, various electronic devices to which the display device according to the embodiments (e.g., the display device DD of FIG. 1) is applied may include image display electronic devices such as a smartphone 10_1a, a tablet PC 10_1b, a laptop 10_1c, a TV 10_1d, and a desktop monitor 10_1e, as well as wearable electronic devices including a display module, such as smart glasses 10_2a, a head-mounted display 10_2b, and a smart watch 10_2c, and vehicle electronic devices including a display module, such as a cluster, center fascia, center information display CID arranged on a dashboard, and a room mirror display 10_3.

The module and the devices according to the embodiments may be applied to a display device included in a computer, a notebook, a mobile phone, a smartphone, a smart pad, a PMP, a PDA, an MP3 player, or the like.

Although the module and the devices according to the embodiments have been described with reference to the drawings, the illustrated embodiments are examples, and may be modified and changed by a person having ordinary knowledge in the relevant technical field without departing from the technical spirit described in the following claims.

What is claimed is:

1. A window module comprising:
a base substrate;
an anti-fingerprint layer on the base substrate; and
an anti-reflective layer on the base substrate and the anti-fingerprint layer, and including:
a first refractive layer under the anti-fingerprint layer,
a second refractive layer under the first refractive layer, and having a second thickness equal to or greater than about 0.4 times a first thickness of the first refractive layer and equal to or less than about 1.5 times the first thickness; and
a third refractive layer between the second refractive layer and the base substrate in a cross-sectional view, having a refractive index greater than a refractive index of the first refractive layer, and a thickness of about 100 nm or more.

2. The window module of claim 1, further comprising:
a fourth refractive layer between the second refractive layer and the third refractive layer in the cross-sectional view, and having a thickness of about 50 nm or more; and
a fifth refractive layer between the third refractive layer and the base substrate in the cross-sectional view, and having a refractive index less than the refractive index of the third refractive layer.

3. The window module of claim 2, wherein the fifth refractive layer has a multi-layered structure including a plurality of sub-refractive layers.

4. The window module of claim 3, wherein the sub-refractive layers include:
at least one first sub-refractive layer having a refractive index equal to or less than about 1.8; and
at least one second sub-refractive layer having a refractive index different from the refractive index of the first sub-refractive layer,
wherein the first sub-refractive layer and the second sub-refractive layer define the fifth refractive layer by being stacked with each other.

5. The window module of claim 2, further comprising:
a first dummy structure between the fifth refractive layer and the base substrate in the cross-sectional view, and including:
a first dummy layer under the fifth refractive layer; and
a second dummy layer under the first dummy layer, and having a refractive index less than a refractive index of the first dummy layer.

6. The window module of claim 5, further comprising:
a second dummy structure between the first dummy structure and the base substrate in the cross-sectional view, and including:
a third dummy layer under the second dummy layer, and having a refractive index greater than the refractive index of the second dummy layer; and
a fourth dummy layer under the third dummy layer, and having a refractive index less than the refractive index of the third dummy layer.

7. The window module of claim 5, wherein the second dummy layer has a multi-layered structure including at least three sub-refractive layers.

8. The window module of claim 2, further comprising:
a first dummy structure between the third refractive layer and the fifth refractive layer in the cross-sectional view, and including:
a first dummy layer under the fifth refractive layer; and
a second dummy layer under the first dummy layer, and having a refractive index greater than a refractive index of the first dummy layer.

9. The window module of claim 8, further comprising:
a second dummy structure between the first dummy structure and the fifth refractive layer in the cross-sectional view, and including:
a third dummy layer under the second dummy layer, and having a refractive index less than the refractive index of the second dummy layer; and
a fourth dummy layer under the third dummy layer, and having a refractive index greater than the refractive index of the third dummy layer.

10. The window module of claim 2, wherein the refractive index of the first refractive layer, a refractive index of the fourth refractive layer, and the refractive index of the fifth refractive layer are equal to or less than about 1.8, and
wherein a refractive index of the second refractive layer and the refractive index of the third refractive layer are equal to or greater than about 1.9.

11. The window module of claim 2, wherein the first refractive layer, the fourth refractive layer, and the fifth refractive layer include at least one selected from a group consisting silicon oxide (SiOₓ) and silicon oxynitride (SiON), and
wherein the second refractive layer, and the third refractive layer include silicon nitride (SiNₓ).

12. The window module of claim 1, wherein the first thickness of the first refractive layer is about 70 nm to about 120 nm.

13. A display device comprising:
a display panel including a planar area and a curved area adjacent to the planar area, and including a plurality of pixels; and
a window module in the planar area and the curved area on the display panel,
wherein the window module includes:
a base substrate;
an anti-fingerprint layer on the base substrate; and
an anti-reflective layer on the base substrate and the anti-fingerprint layer,
wherein the anti-reflective layer includes:
a first refractive layer under the anti-fingerprint layer,
a second refractive layer under the first refractive layer, and having a second thickness equal to or greater than about 0.4 times a first thickness of the first refractive layer and equal to or less than about 1.5 times the first thickness; and
a third refractive layer between the second refractive layer and the base substrate in a cross-sectional view, having a refractive index greater than a refractive index of the first refractive layer, and a thickness of about 100 nm or more.

14. The display device of claim 13, wherein the window module includes:
a fourth refractive layer between the second refractive layer and the third refractive layer in the cross-sectional view, and having a thickness of about 50 nm or more; and
a fifth refractive layer between the third refractive layer and the base substrate in the cross-sectional view, and having a refractive index less than the refractive index of the third refractive layer.

15. The display device of claim 14, wherein the fifth refractive layer has a multi-layered structure including a plurality of sub-refractive layers.

16. The display device of claim 14, wherein the window module includes:
at least one dummy structure between the fifth refractive layer and the base substrate, and in which two dummy layers having different refractive indexes are stacked.

17. The display device of claim 14, wherein the refractive index of the first refractive layer, a refractive index of the fourth refractive layer, and the refractive index of the fifth refractive layer are equal to or less than about 1.8, and
wherein a refractive index of the second refractive layer and the refractive index of the third refractive layer are equal to or greater than about 1.9.

18. The display device of claim 14, wherein the first thickness of the first refractive layer is about 70 nm to about 120 nm.

19. An electronic device comprising:
a power module; and
a display device to which power from the power module is configured to be supplied, and including a display panel and a window module on the display panel,
wherein the window module includes:
a base substrate;
an anti-fingerprint layer on the base substrate; and
an anti-reflective layer on the base substrate and the anti-fingerprint layer,
wherein the anti-reflective layer includes:
a first refractive layer under the anti-fingerprint layer,
a second refractive layer under the first refractive layer, and having a second thickness equal to or greater than about 0.4 times a first thickness of the first refractive layer and equal to or less than about 1.5 times the first thickness; and
a third refractive layer between the second refractive layer and the base substrate in a cross-sectional view, having a refractive index greater than a refractive index of the first refractive layer, and a thickness of about 100 nm or more.

20. The electronic device of claim 19, wherein the window module includes:
a fourth refractive layer between the second refractive layer and the third refractive layer in the cross-sectional view, and having a thickness of about 50 nm or more; and
a fifth refractive layer between the third refractive layer and the base substrate in the cross-sectional view, and having a refractive index less than the refractive index of the third refractive layer.
